(19) United States
(12) Patent Application Publication
(10) Pub. No.: US 2017/0194553 A1
(43) Pub. Date: Jul. 6, 2017

(54) Laterally Curved Actuators of Shape Memory Materials

(71) Applicant: University of Florida Research Foundation, Inc., Gainesville, FL (US)

(72) Inventors: Peter G. Ifju, Newberry, FL (US); Jason T. Cantrell, Macclenny, FL (US)

(21) Appl. No.: 15/316,251

(22) PCT Filed: Jun. 5, 2015
(86) PCT No.: PCT/US2015/034432

§ 371 Date: Dec. 5, 2016

Related U.S. Application Data
(60) Provisional application No. 62/008,201, filed on Jun. 5, 2014.

(51) Int. Cl. H01L 41/09; B32B 37/14

(52) U.S. Cl. CPC H01L 41/09; B32B 37/144; F16D 2121/32

(57) ABSTRACT

A unimorph composite actuator (UCA) has a deformable substrate that has a lateral curvature relative to an axis or curve of the substrate and at least one shape memory material (SMM) attached to at least a portion of a face of the substrate. The curvature of the substrate assists the restoration of the original structure after being fixed in a deformed conformation. The SMM can be a shape memory polymer (SMP).

### CROSS-REFERENCE TO A RELATED APPLICATION

This application claims the benefit of U.S. Provisional Application Ser. No. 62/008,201, filed Jun. 5, 2014, the disclosure of which is hereby incorporated by reference in its entirety, including all figures, tables and drawings.

This invention was made with government support under sub-contract 11-S587-102-01-C1, prime contract FA8650-07-D-5800, awarded by the Air Force Research Laboratory. The government has certain rights in the invention.

### BACKGROUND OF INVENTION

Shape memory polymers (SMP) and other shape memory materials (SMM) are smart materials used in reconfigurable structures. Smart materials include piezoelectric, shape memory alloys, and SMPs. Smart materials are practical for various applications, including: shape memory alloys in orthodontic treatments; piezoelectric actuators for control of micro air vehicles; shape memory polymers as cardiovascular stents; and a multitude of smart materials for the morphing of aircraft structures. SMMs are valued for their potential use in adaptive structures in various applications, such as, micro air vehicles (MAVs) and morphing aircraft. SMPs have the ability to change their shape upon application of external stimuli, such as, temperature, electricity, magnetism, or light. For example, Veriflex-S® is an SMP that uses an external thermal stimulus to allow reconfiguration and recovery. Veriflex SMPs have been used in applications that include active disassembly for recycling, deployment of satellite solar panels, and deployable aircraft wings.

Veriflex-S® can display two stiffnesses and material behaviors characterized by a high glassy modulus and a low rubbery modulus. At temperatures below its glass transition temperature (T_{g}), the material is relatively stiff and has a high elastic modulus. When the SMP is heated above its T_{g}, the modulus drops by several orders of magnitude. This transition from the glassy to the rubbery state is illustrated in FIG. 1. In the rubbery state, SMPs can deform up to 400% and in the glass state, below T_{g}, the SMPs maintain the new shape indefinitely. The original shape can be recovered by reheating the SMP above T_{g}. Generally, the glassy state is readily maintained at temperatures lying at least 10° C. below the T_{g}, while the rubbery state is readily maintained at temperatures of more than 10° C. above the T_{g}. The area in between these glassy and rubbery states is a transition region in which the elastic modulus transitions rapidly.

FIG. 2 illustrates an ideal shape memory thermomechanical cycle. The SMP article begins in its original shape at a high modulus below T_{g}, and then heat is applied to the sample, causing the modulus to fall into the rubbery state. Once in the rubbery state, the sample is bent into the desired deformed shape, illustrated as a U-shape, which upon cooling to below T_{g}, is locked into the deformed shape. Upon the reapplication of heat, the SMP article will release and return to the unconstrained original form. Ideally, the SMP article would return to 100% of the original shape and retain this shape upon cooling below the T_{g}. In reality, Veriflex SMPs recover to achieve a final shape that is near the original shape. This results, as indicated in FIG. 3, because the actual stress-strain-temperature behavior for an SMP during a thermomechanical cycle differs when the load is released, which is shown as the fifth step in the cycle. Ideally, the SMP locks into its current configuration. However, in realized SMPs, some relaxation occurs. Once reheated and cooled, the SMP is unable to recover fully and exhibits some degree of shape recovery loss. The recoverability of SMPs has been shown to vary between 65-95% of the original shape after repeated cycling, depending upon testing conditions. Despite displaying less than complete recovery, SMPs are advantageous over other shape memory materials because of benefits that include low cost, low density, and high deformability.

A major deficiency of shape memory material (SMM) unimorphs, which comprise an active SMM layer and an inactive support material, is a permanently unrecovered shape after a single or multiple stimulus cycles. Hence there is a need for a means to assist the recoverability of SMPs, such as, Veriflex-S®. To this end, an SMP in a unimorph composite actuator (UCA) configuration has the potential to promote recovery in excess of 95% of the SMP article. A UCA is an element with a bi-stable configuration consisting of one active layer—the SMP—to which the stimulus is applied and an inactive layer that supports the active layer.

### BRIEF DESCRIPTION OF DRAWINGS

FIG. 1 shows a generalized plot of elastic modulus (E) versus temperature for Veriflex-S® shape memory polymer (SMP) where the graph is divided into the plastic region (T<T_{g}), transition region, and rubbery region (T>T_{g}).

FIG. 2 shows a shape memory cycle for thermally activated SMPs, where the SMP as originally programmed is a flat beam (1), heated above T_{g} (2), deformed into the desired configuration (3), cooled (4), released from loading (5), heated again (6), and finally allowed to recover to its deployed flat state while cooling (7).

FIG. 3 is a plot of the stress-strain-temperature behavior of an SMP during a thermomechanical cycle.

FIG. 4 is a photograph of a sample container holding a curved unimorph composite actuator (UCA) according to an embodiment of the invention.

FIG. 5 shows an illustration of a curved UCA, according to an embodiment of the invention, which is labeled for the structural features that are readily varied to optimize the UCA structure.

FIG. 6 shows the difference between: FIG. 6(a) a UCA without curvature from a flat substrate; FIG. 6(b) a UCA with concave transverse curvature according to an embodiment of the invention; and FIG. 6(c) a UCA with convex transverse curvature, according to an embodiment of the invention.

FIG. 7 illustrates the process of converting digital image correlation (DIC) data to the desired coordinate system and removing rigid body motion for the analysis of UCAs.

FIG. 8 shows plots for the average cooling profile of five temperature cycles in the deployed configuration.

FIG. 9 shows plots of lengthwise versus out-of-plane deflection for: FIG. 9(a), zero to ten minutes; and FIG. 9(b), ten to thirty minutes for a flat UCA at various times during a cooling cycle.

FIG. 10 shows plots of lengthwise versus out-of-plane deflection for: FIG. 10(a), zero to ten minutes; and FIG. 10(b), ten to thirty minutes for a 63.5 mm concave UCA, according to an embodiment of the invention, at various times during a cooling cycle.

FIG. 11 shows plots of lengthwise versus out-of-plane deflection for: FIG. 11(a), zero to ten minutes; and FIG. 11(b), ten to thirty minutes for a 63.5 mm convex UCA, according to an embodiment of the invention, at various times during a cooling cycle.

FIG. 12 shows the strain fields on the flat UCA in the FIG. 12(a) x-direction and FIG. 12(b) y-direction after cooling for thirty minutes, where the area of interest for strain calculations is area enclosed by the box in the center of the specimens.

FIG. 13 shows plots of the average strain at the center of the UCA during the deployed cooling cycle, Step 7 of FIG. 2, for flat, concave and convex UCAs, according to an embodiment of the invention.

FIG. 14 shows plots of the widthwise position versus out-of-plane position (z+w) for the reference and ten to thirty minutes into the cooling cycle for the FIG. 14(a) flat, FIG. 14(b) concave, and FIG. 14(c) convex UCAs, according to an embodiment of the invention, in the deployed position.

FIG. 15 shows plots of the average strain at the center of the UCAs during the deformed/stored cooling cycle, Step 4 of FIG. 2, for the flat, concave, and convex UCAs, according to an embodiment of the invention.

FIG. 16 shows plots of the widthwise position versus out-of-plane position (z+w) for the reference and ten to thirty minutes into the cooling cycle for the FIG. 16(a) flat, FIG. 16(b), concave and FIG. 16(c) convex UCAs, according to an embodiment of the invention, in the stored position.

FIG. 17 shows bar graphs of the maximum out-of-plane deflection at the end of the 60 minute observation period for the deployed state keeping thickness constant for the FIG. 17(a) thin SMP and FIG. 17(b) thick SMP UCAs.

FIG. 18 shows bar charts for out-of-plane deflection varying the UCA width and SMP thickness while maintaining constant curvature for: FIG. 18(a) flat curvature; FIG. 18(b) a 127 mm radius of curvature, according to an embodiment of the invention; and FIG. 18(c) a 62.5 mm radius of curvature, according to an embodiment of the invention.

FIG. 19 shows bar charts for out-of-plane deflection varying the UCA radius of curvature and SMP thickness while maintaining constant UCA width for: FIG. 19(a), 25.4 mm width; FIG. 19(b), 38.1 mm width; and FIG. 19(c), 50.8 mm width for flat and curved UCAs, according to an embodiment of the invention.

FIG. 20 shows plots of lengthwise versus out-of-plane deflection for the 635_16_254 UCA, according to an embodiment of the invention, at various times during a cooling cycle.

FIG. 21 shows plots for lengthwise position versus out-of-plane deflection for the 635_16_381 UCA, according to an embodiment of the invention, at various times during a cooling cycle.

FIG. 22 shows plots for lengthwise position versus out-of-plane deflection for the 635_16_508 UCA, according to an embodiment of the invention, at various times during a cooling cycle.

FIG. 23 shows a plot of the widthwise position versus out-of-plane position for the thick SMP, wide substrate UCAs with FIG. 23(a) flat curvature and FIG. 23(b) low transverse curvature, according to an embodiment of the invention.

FIG. 24 shows plots for lengthwise position versus out-of-plane deflection for the 000_08_381 UCA at various times during a cooling cycle.

FIG. 25 shows plots for lengthwise position versus out-of-plane deflection for the 127_08_381 UCA, according to an embodiment of the invention, at various times during a cooling cycle.

FIG. 26 shows plots for lengthwise position versus out-of-plane deflection for the 635_{—} 08_381 UCA, according to an embodiment of the invention, at various times during a cooling cycle.

FIG. 27 shows plots for lengthwise position versus out-of-plane deflection for: FIG. 27(a), eight 000_08_381 samples and FIG. 27(b), their corresponding standard deviations; and FIG. 27(c), eight 625_08_381 samples, according to an embodiment of the invention, and FIG. 27(d), their corresponding standard deviations at each lengthwise position.

FIG. 28(a) shows illustration of post-processed images for calculation of the deflection angles for a UCA and FIG. 28(b) is a diagram illustrating the definition of positive and negative deflection angles.

FIG. 29 shows plots of the deflection angle versus time for FIG. 29(a) the first sixty minutes, FIG. 29(b) four hours, and FIG. 29(c) seven days for the three UCAs.

FIG. 30 is a bar graph for UCAs' deflection angles keeping thickness constant for the FIG. 30(a) thin SMP and FIG. 30(b) thick SMP at seven days.

FIG. 31 shows plots of the deflection angle versus time for FIG. 31(a) the first sixty minutes, FIG. 31(b) four hours, and FIG. 31(c) seven days of the thin SMP, intermediate substrate, UCAs with flat, low, and high transverse curvature, respectively.

### DETAILED DISCLOSURE

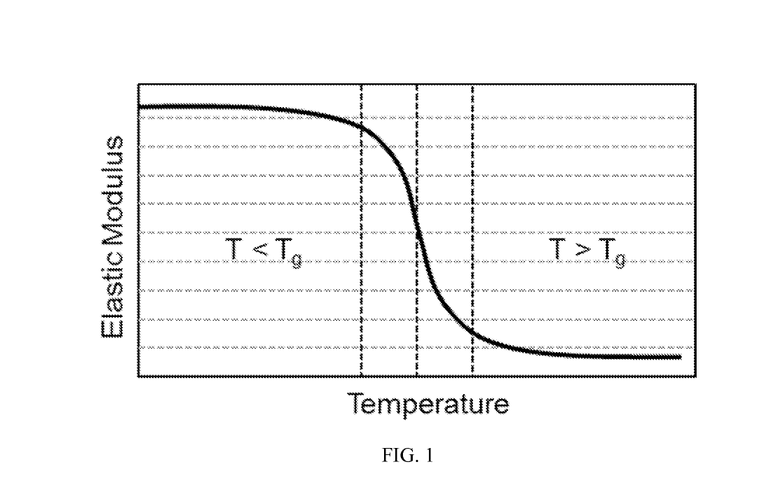

Embodiments of the invention are directed to a unimorph composite actuator (UCA) incorporating lateral curvature in a substrate to give excellent shape recovery to an SMM unimorph. UCAs, according to an embodiment of the invention, comprise an SMP layer bonded to a curved substrate. The UCA employs a lateral curvature that significantly reduces the residual deformation while increasing shape memory recoverability, which could be tailored to enhance the performance of shape memory polymers in reconfigurable arrangements. Recoveries of the UCAs are more than an order of magnitude better than traditional flat UCAs. Although the following disclosure is exemplified by the use of SMPs, any SMM can be used, including shape memory alloys (SMAs) and piezoelectric materials, where unlike that shown in FIG. 1, the SMA undergo two different temperature transformations, one from austenite to martensite upon cooling and from martensite to austenite upon heating. The piezoelectric materials undergo lesser deformations and do so in response to application of an electrical potential rather than temperature. In all cases the substrate structure can promote recovery to the original unstressed shape.

The UCA can be used in any device that requires switching between two states, one state being a deformed state and the other being the equilibrium state that is fixed into the SMP upon its formation. Though the exemplary embodiments are for a simple UCA that has lateral curvature, which resembles a portion of a cylinder in shape that has a length parallel to the central axis of the cylinder and a width that is perpendicular to the hypothetical central axis, the UCAs according to embodiments of the invention can have other shapes as long as curvature in at least one dimension is present. The UCA comprises an “elastic” substrate that is capable of being bent or otherwise deformed or deflected along at least one axis or other defining curve of the equilibrium state. The substrate can be a composite, a metal, or a thermoplastic, which is employed at temperatures such that at the highest temperature encountered by the UCA no flow results in the substrate; for example, all temperatures are below a substrate material's glass transition temperature (T_{g}) or melting temperature (Tₘ). The substrate is sufficiently thin, such that a reversible deflection along a defining axis or defining curve can be performed at an accessible force for the use of the UCA but inherently the substrate will return to its desired shape. For example, the UCA can be employed as an airfoil when in the equilibrium state and transformed into a more compact state for storage of the device employing the airfoil.

The SMP can be a polymeric system that is covalently or physically cross-linked, such that there is no relative disorientation of the effective cross-links upon heating above the polymer's T_{g}, such that the cross-linking sites cannot exchange and cannot translate into other positions that generate an energetically preferable state. The effective cross-linking density is at a level that does not restrict deformation of the polymeric network when the temperature is raised above the T_{g} of a continuous or semi-continuous phase within the network. In general, the SMP can be in the form of: (I) a chemically cross-linked glassy thermoset; (II) a chemically cross-linked semi-crystalline rubber; (III) a physically cross-linked thermoplastic; and (IV) a physically cross-linked block copolymer. Of the (I) chemically cross-linked glassy thermosets, exemplary SMPs are: P(MMA-co-VP)-PEG semi-IPNs; copolyester; P(AA-co-MMA)-PEG; PMMA-PBMA copolymers; PET-PEG copolymers; P(MA-co-MMA)-PEGs; Soybean oil copolymers with styrene and DVB; styrene copolymers; thermosetting PUs (water swollen); thermosetting PUs (ester type); dehydrochlorinated cross-linked PVC; polynorbornene; or ultrahigh MW PMMA. Of the (II) chemically cross-linked semi-crystalline rubbers, exemplary SMPs are: Poly-caprolactone; EVA+nitrile rubber; PE, Poly-cyclooctene; PCO-CPE blend; PCL-BA copolymer; Poly(ODVE)-co-BA; or EVA+CSM. Of the (III) physically cross-linked thermoplastics, exemplary SMPS are: POSS telechelics; PLAGC multiblock copolymers; Aramid/PCL; PVDF/PVAc Blends; Poly(ketone-co-alcohol); PCL-b-ODX; PLA/PVAc blends; Poly(1-hexadecene)-co-PP; PE-co-PMCP; POSS-PN block copolymers; PA-PCL Polyamides; PET-co-PEOs; PE-co-Nylon 6; or PS-TPB. Of the (IV) physically cross-linked block copolymers, exemplary SMPs are: POSS/PDLA-co-PCL/MDI; 4,4′-Dihydroxybiphenyl (DHBP)/PCL blend with phenoxy resin or PVC/Hexamethylene diisocyanate (HDI); 1,6-HD/HDI-1,2-BD/4,4′-MDI; 1,4-Butanediol/Poly(ethylene adipate)/MDI; 1,4-Butane glycol, ethylene glycol, bis(2-hydroxyethyl) hydroquinone, bisphenol A+ethylene oxide, and/or bisphenol A+propylene oxide/Polypropylene glycol, 1,4-butaneglycol adipate, polytetramethylene glycol, polyethylene glycol, and/or bisphenol A+propylene oxide/2,4-Toluene diisocyanate, 4,4′-diphenyl-methane diisocyanate, and/or hexamethylene diisocyanate; 1,4-BD/Poly(tetramethylene glycol) (PTMG)/MDI; 1,4-BD/PCL diol/MDI; BEBP or BHBP/PCL diol/MDI; DHBP/PCL diol, 4000 Da/HDI; 1,4-BD/Poly(tetramethylene oxide) glycol/(PTMO) MDI; or BD+DMPA/PCL diol, 2000, 4000, 8000 Da/MDI. The transition region, as shown in FIG. 1, can be centered at temperatures between 0 and 150° C., and can be selected for the application for use of the UCA, which defines the composition and type of the SMP included in the UCA. Exemplary embodiments of the invention are illustrated using a carbon fiber epoxy composite substrate and Veriflex-S®, which is a poly(styrene-co-vinyl neodecanoate-divinylbenzene) terpolymer network. However, any SMP can be substituted for Veriflex-S® and other substrates can be used. In some embodiments of the invention, the substrate and the SMP can be of compatible materials, where, for example, the substrate can be a homopolymer of a monomer that is included in a copolymer of the SMP. For example, a styrene copolymer having a T_{g} sufficiently below the T_{g} of polystyrene, can be fused to a surface of a polystyrene substrate thermally at a temperature in excess of the T_{g} of polystyrene without an adhesive, and used over a temperature regime that does not rise to the T_{g} of polystyrene.

Where the SMM is a SMA, materials that can be used include, but are not limited to, Ag—Cd 44/49 at. % Cd, Au—Cd 46.5/50 at. % Cd, Cu—Al—Ni 14/14.5 wt. % Al and 3/4.5 wt. % Ni, Cu—Sn approx. 15 at. % Sn, Cu—Zn 38.5/41.5 wt. % Zn, Cu—Zn—X (X═Si, Al, Sn), Fe—Pt approx. 25 at. % Pt, Mn—Cu 5/35 at. % Cu, Fe—Mn—Si, Pt alloys, Co—Ni—Al, Co—Ni—Ga, Ni—Fe—Ga, Ti—Pd in various concentrations, Ni—Ti (˜55% Ni), Ni—Ti—Nb, and Ni—Mn—Ga. Piezoelectric material that can be employed include, but are not limited to, Lead zirconate titanate (Pb[ZrₓTi₁₋ₓ]O₃ 0≦x≦1), Potassium niobate (KNbO₃), Lithium niobate (LiNbO₃), Lithium tantalate (LiTaO₃), Sodium tungstate (Na₂WO₃), Zinc oxide (ZnO), Ba₂NaNb₅O₅, Pb₂KNb₅O₁₅, Sodium potassium niobate ((K,Na)NbO₃), Bismuth ferrite (BiFeO₃), Sodium niobate NaNbO₃, Bismuth titanate Bi₄Ti₃O₁₂, Sodium bismuth titanate Na_{0.5}Bi_{0.5}TiO₃, and Polyvinylidene fluoride (PVDF).

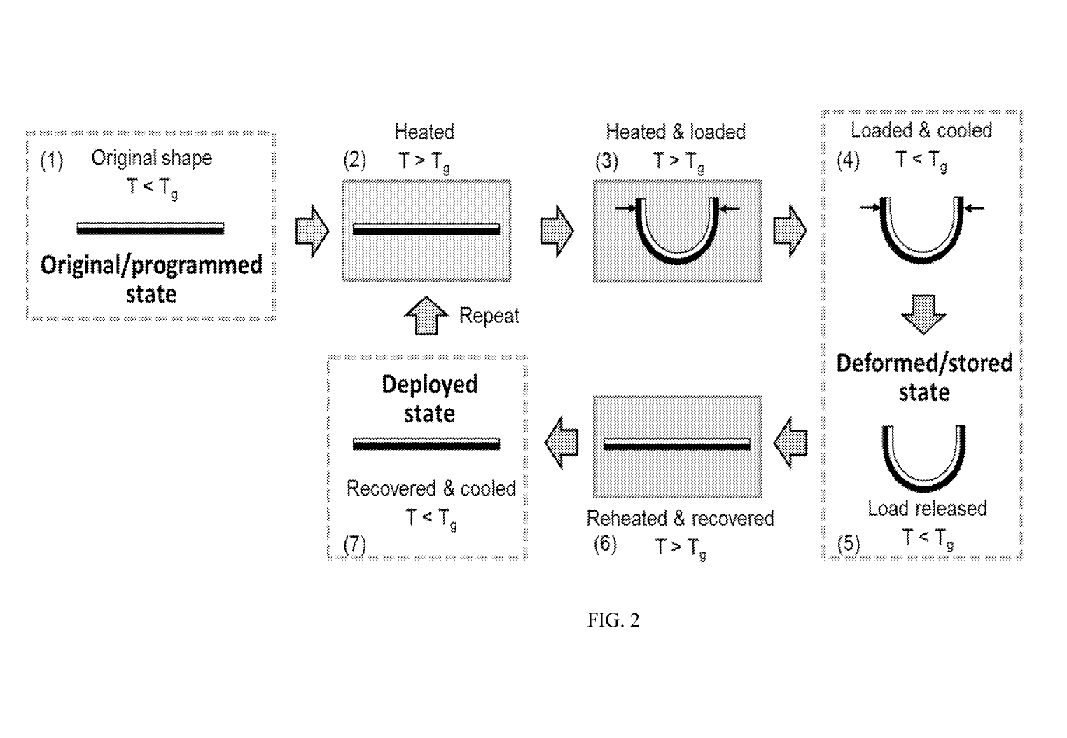

The UCA can be prepared by forming or providing the substrate in a desired shape, including the curvature that is needed for the UCAs, according to embodiments of the invention. The SMP can then be combined with the substrate. The combination can be constructed by forming the SMP on the substrate or by adhering the SMP to the substrate. The UCA can be mechanically deformed at temperatures above the T_{g}, or the Tₘ, of the SMP and allowed to cool to a temperature below the T_{g}, or Tₘ, of the SMP. This transformation locks the UCA in the deformed state, which is not in the thermodynamic minimum conformation, but is retained in this stressed state while the temperature is maintained below that of a thermal transition region, as shown in FIG. 2.

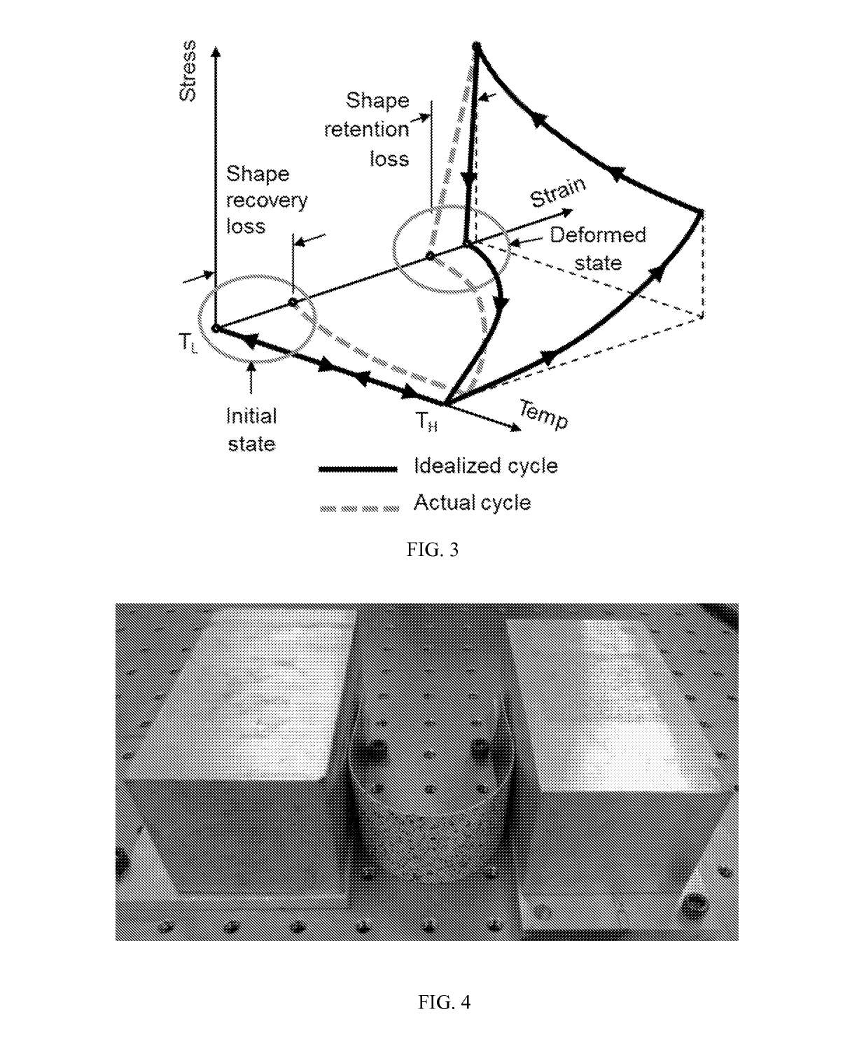

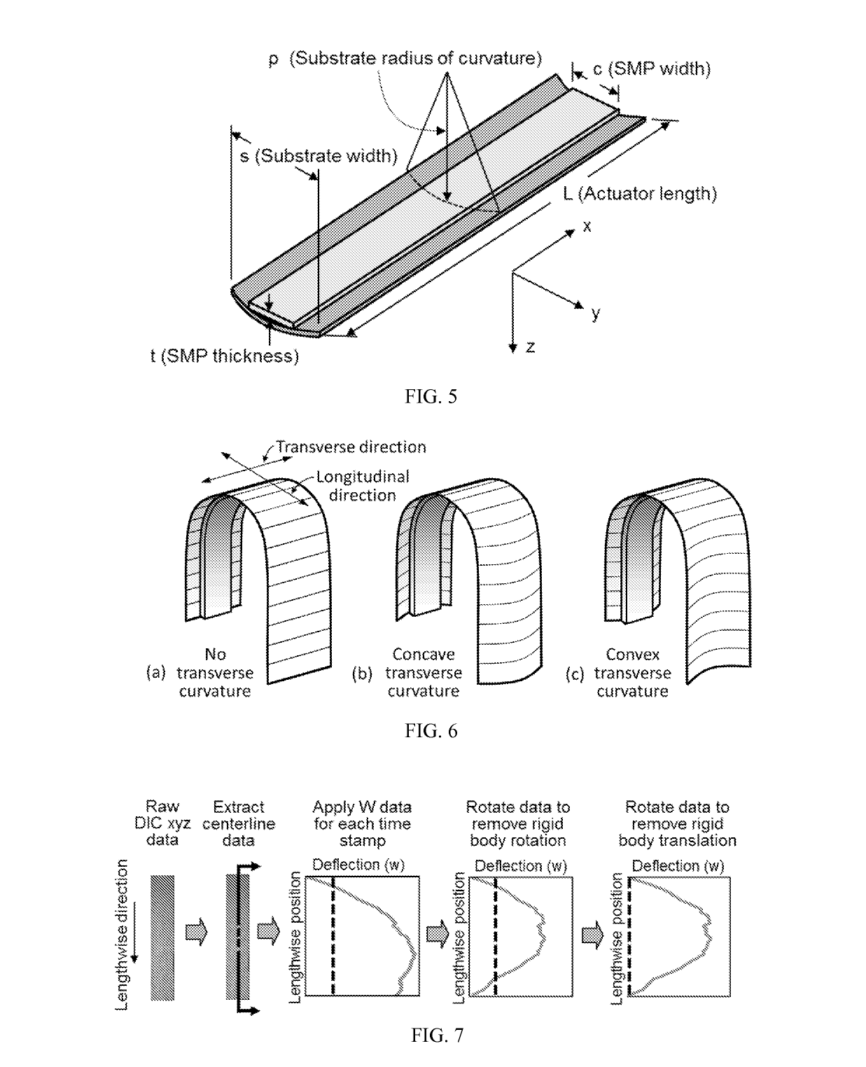

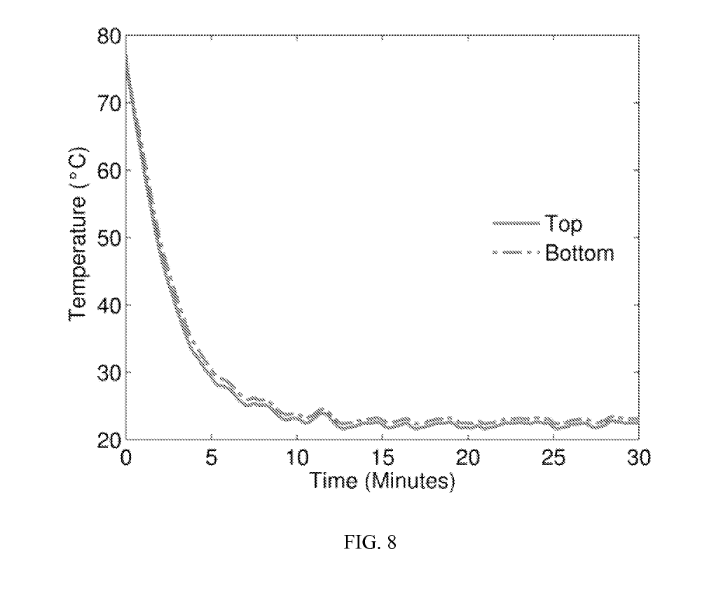

FIG. 3 shows the deviation of state-of-the-art SMPs from ideal SMPs which return to specifically the shapes in which they were prepared before deformation with heating, without the imposition of stress. The UCAs, according to embodiments of the invention, overcome the deviation from ideal behavior by having a substrate with a lateral curved structure relative to the axis of intended deformation. The UCA's substrate assists return to the original prepared structure, which existed before deformation, to a high extent because of this substrate structure. The lateral curvature can be a relatively small deviation from planarity, or flatness, and the deformation, or deflection, can be such that the deviation from planarity can be considered concave or convex with respect to the surface where the SMP is joined to the substrate along a line parallel to the hypothetical axis of a cylinder. Alternatively, the deviation from planarity can be considered concave or convex with respect to the inner surface of any curvature imposed by the deformation. Hence, a UCA can have a concave curvature with respect to the SMP while exhibiting a convex curvature with respect to the deformation inner surface. For example, FIG. 5 illustrates a concave curvature with respect to the SMP, which, as shown in FIG. 6(b), is also concave with respect to the deformation inner surface. As shown in FIG. 6(c), the curvature is convex with respect to the SMP and is convex with respect to the deformation inner surface. If the illustrated UCAs in FIG. 6 were changed such that the SMP were situated on the outside deformation surface, for example, in FIG. 6(b), the curvature of the UCA would be convex with respect to the SMP while still concave with respect to the deformation inner surface. In some embodiments of the invention, the SMP is attached to both faces of the substrate, wherein all lateral curvature is relative to the axis of deformation of the UCA. The entire substrate can be coated with the SMP. A convex or concave UCA can be superior to the alternative depending upon the nature of the materials used to form the UCA and the mode of deformation intended. A UCA can act in a convex and a concave mode. In an embodiment of the invention, the deformed state can be concave and the unstressed equilibrium minimum state can be convex, or, oppositely, the deformed state can be convex and the unstressed equilibrium minimum state can be concave.

### Methods and Materials

### Unimorph Composite Actuator (UCA) Fabrication

Sample UCAs consist of an SMP layer bonded to a graphite fiber/epoxy substrate. Flat carbon fiber composite unimorphs and transverse curvature carbon fiber composite unimorphs were fabricated as follows. A single layer of a [±45°] oriented, plain weave, bi-directional carbon fiber epoxy resin sheet was cut and placed on a Teflon covered plate or a curved tooling board. The [±45°] fiber configuration was used versus a [0°/90°] because it allowed for the CF to be rolled to a smaller diameter in the stored state and was more stable during storage. The assembly was covered by an additional layer of Teflon, vacuum bagged, and cured at 130° C. for four hours. After curing, the carbon fiber composite was cut to the appropriate size. A styrene copolymer network, Veriflex-S® shape memory polymer, Cornerstone Research Group, Inc., USA panel was bonded to the carbon fiber composite using Araldite 2011, a two-part epoxy. The UCAs were coated with a base coat of flat white spray paint and randomly speckled for digital image correlation (DIC) using flat black spray paint.

### Digital Image Correlation (DIC) Set-Up

The DIC system is a non-contact full-field shape and deformation technique developed at the University of South Carolina. The DIC system employed used two Point Grey Research 5-megapixel grayscale cameras to simultaneously capture images of the random speckle pattern applied to the samples. The cameras were calibrated via a high contrast dot pattern of known diameter and spacing. A 9×9 grid of points with a separation of 10 mm was used for calibration. After calibration, the system was used to photograph the UCA and determine deflection as a function of time. Reference images of the beams were initially taken after the samples were painted. Subsequent images were taken before starting each testing cycle. These images were contrasted against images taken over the hour observation time to determine the deflection as the sample cooled. Images were captured via VIC Snap 2009 and processed via VIC-3D 2009 to determine deformations.

### Thermocouple Set-Up

A transversely curved UCA was monitored during the deployed and stored cooling stages to develop a cooling profile over time. The UCA was outfitted with two Omega SA1 self-adhesive K-type thermocouples. A thermocouple was placed in the center of the UCA on both the top and bottom surfaces to monitor temperature.

### Environmental Chamber Set-Up

The UCAs were placed in a Sun Systems Model EC12 environmental chamber and the temperature was brought to a desired value greater than the SMP's T_{g}. The temperature was monitored via a thermocouple inside of the chamber and confirmed via a Fluke 561 series infrared thermometer. Beam samples were placed on a Teflon plate within the chamber to allow for full expansion under elevated temperature conditions.

### UCA Sample Holder Set-Up

Upon removal from the environmental chamber, samples were folded into a U-shaped configuration, as shown in FIG. 4, and stored in a tabletop retainer to ensure equivalent loading conditions for all actuators. This apparatus consists of five ¼-20 bolts in a U configuration secured to the table that prevent samples from folding inwardly, and two metal blocks spaced 60 mm apart to constrain the samples in the outward direction.

### Measuring UCA Recoverability by DIC

Step 1. Acquire an initial (reference) image of the undeformed speckle pattern on the UCA.

Step 2. Place the undeformed UCA in the environmental chamber for one hour at 85° C.

Step 3. Bend the UCA into a U-shaped configuration within the holder and cool for one hour in the stored configuration.

Step 4. Return the UCA to the environmental chamber at 85° C. for one hour.

Step 5. Remove the UCA from the oven.

Step 6. Monitor the UCA via DIC while cooling to room temperature.

### Materials Characterization

Before the UCAs were characterized as a unit the constituents, the plain weave; bi-directional carbon fiber; and the Veriflex-S® SMP were characterized individually. The epoxy and spray paint were not characterized due to their negligible thickness, 0.15 mm and 0.05 mm, respectively, with respect to the SMP and substrate (1.6 mm and 0.35 mm respectively) in the UCA. The Young's modulus and Poisson's ratio for both of these materials were calculated from a combination of tension tests and DIC to measure the full-field displacements under loading conditions at room temperature. The material properties for the CFRP were gathered with the fibers in the [±45°] orientation to coincide with the substrate lay-up. The load and corresponding strains were used to calculate the values provided in Table 1, below. Coefficient of thermal expansion (CTE) was determined by placing the specimens on a specialized hot plate and monitoring strain with respect to temperature via DIC. These strain values were validated by measuring the CTE of an aluminum sample concurrently with the Veriflex-S® and CFRP. Glass transition temperatures were taken from the manufacturer's respective published values. The glass transition temperature of the carbon fiber refers to the epoxy matrix's transition temperature, which is well above the glass transition temperature of Veriflex-S® and the experimental operating temperature. Coefficient of variation (CV), which is defined as the ratio of the standard deviation to the mean, is provided to display the extent of variability of the data.

TABLE 1
Material properties for [±45°] oriented, plain weave, bi-directional
carbon fiber and Veriflex-S ® shape memory polymer

| | CFRP [±45°] | | Veriflex-S ® | |
|---|---|---|---|---|
| Property | Value | CV | Value | CV |
| Coefficient of | 2.5 ± 0.2E⁻⁶ K⁻¹ | 8% | 160 ± 15E⁻⁶ K⁻¹ | 9.6% |
| Thermal | | | | |
| Expansion (α) | | | | |
| Young's Modulus | 11.8 ± 0.3 GPa | 2.8% | 1.1 ± 0.05 GPa | 4.5% |
| (E) | | | | |
| Poisson's Ratio (ν) | 0.79 ± 0.02 | 2.5% | 0.39 ± 0.01 | 2.6% |
| Glass Transition | 121° C. | — | 62° C. | — |
| Temperature* (T_{g}) | | | | |

*Manufacturer published values

### UCA Investigation

Out-of-plane deflection (w) of the UCA was performed using UCAs of 200 by 38 mm that are flat (zero curvature) or have a 63.5 mm radius of curvature carbon fiber epoxy composite substrates. The substrates had a thickness of 0.35 mm. A 12.7 mm wide and 1.6 mm thick strip of flat SMP adhered via a 0.15 mm thick layer of Araldite® 2011 epoxy to the center of the carbon fiber substrate. The total UCA thickness was 2.15 mm which included a 50 μm layer of paint on the substrate surface for DIC measurements. FIG. 5 shows a curved UCA. FIG. 6 shows a schematic of the flat, concave, and convex UCA in their U shape.

Processing of the acquired DIC data was carried out to determine the deflection for each UCA over time. Processing involved collecting the XYZ coordinates and UVW displacements for the centerline of each sample at desired times. Using an Excel spreadsheet, deformation (W) data was sorted by time and shifted to the desired coordinate system using MATLAB. Once transformed into the X-Z plane, the data are rotated to eliminate rigid body motion, assuring rotation of the sample in the X (lengthwise) direction to maintain correct displacement directions. After rotation, vertical translation to the X-axis ensures all images can be compared in the same coordinate system. This process is illustrated in FIG. 7.

The cooling temperature as a function of time was measured during cool down for the deployed state, Step 7 of FIG. 2. A type-K self-adhesive thermocouple was placed on the top and bottom surface to monitor the temperature as the UCA cooled. Five thermo-mechanical trials were conducted on a single UCA. The thermocouple measurements were accurate within ±1.5° C. and the data shows that there is no statistical difference between the top and bottom surface temperatures during cooling. The UCA cooled from 75° C. to 25° C. in the first six minutes and reached ambient temperature on the surface at approximately ten minutes.

Data for the flat and concave curved UCAs were collected in two minute intervals for the entire thirty minutes of cooling. The centerline shape was measured for the reference (before any temperature cycle) and at various times after the temperature cycle. To obtain the deformation, the reference shape was subtracted from the shape after the temperature cycle. To obtain the out-of-plane position (z+w) the residual deformation (w) seen was added to the original undeformed shape (z) of the UCA before the thermo-mechanical cycle. To properly control for manufacturing defects, only the deflection from the original shape is included in the resulting deflections. Repeatability and uncertainty experiments were performed during initial experiments and detailed experiments and expanded design space experiments, respectively. These results confirm the repeatability and statistical significance of the experimental results.

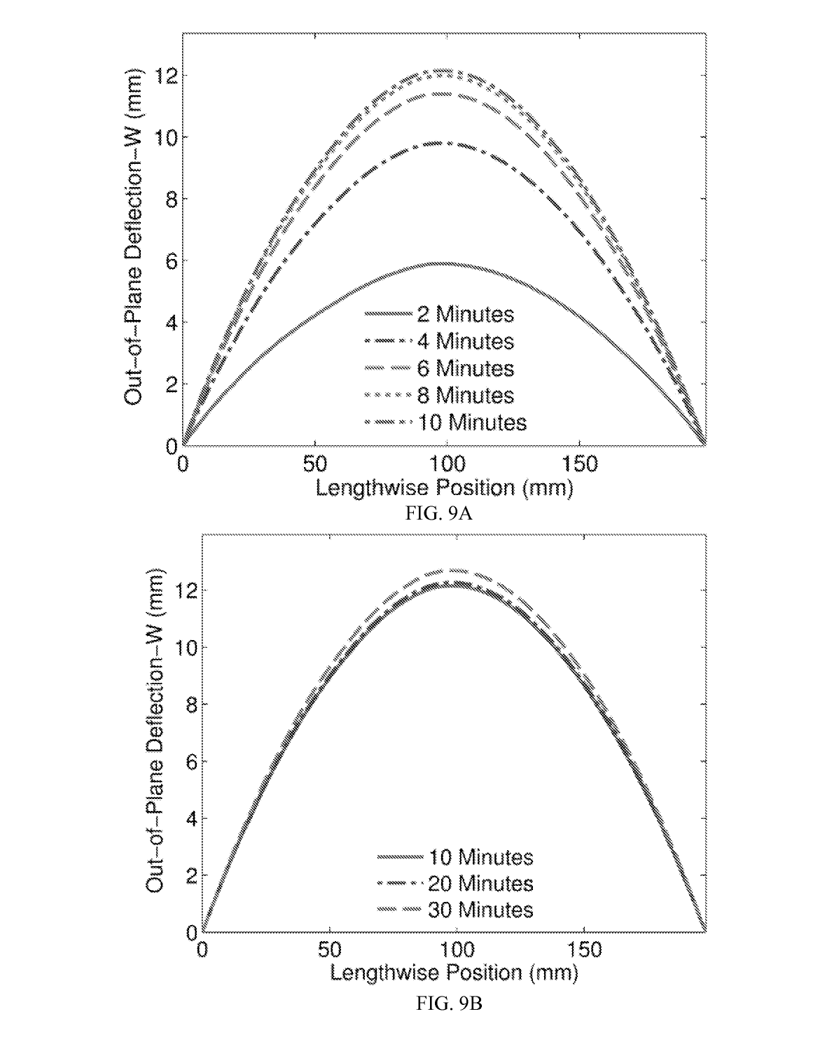

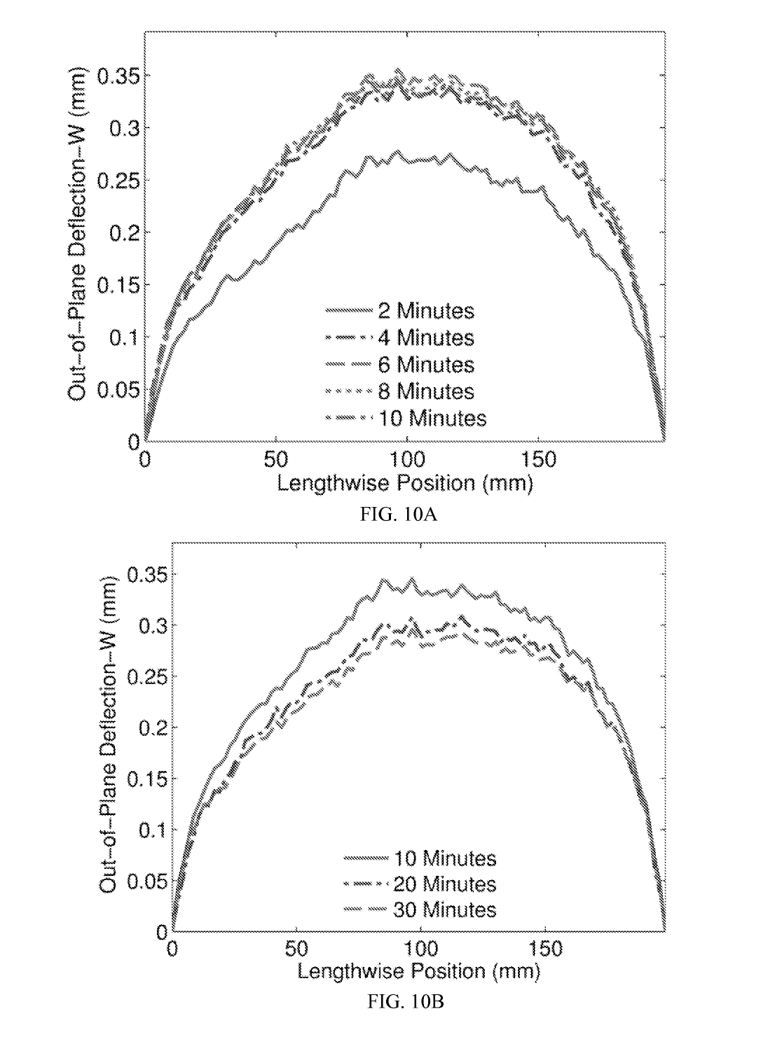

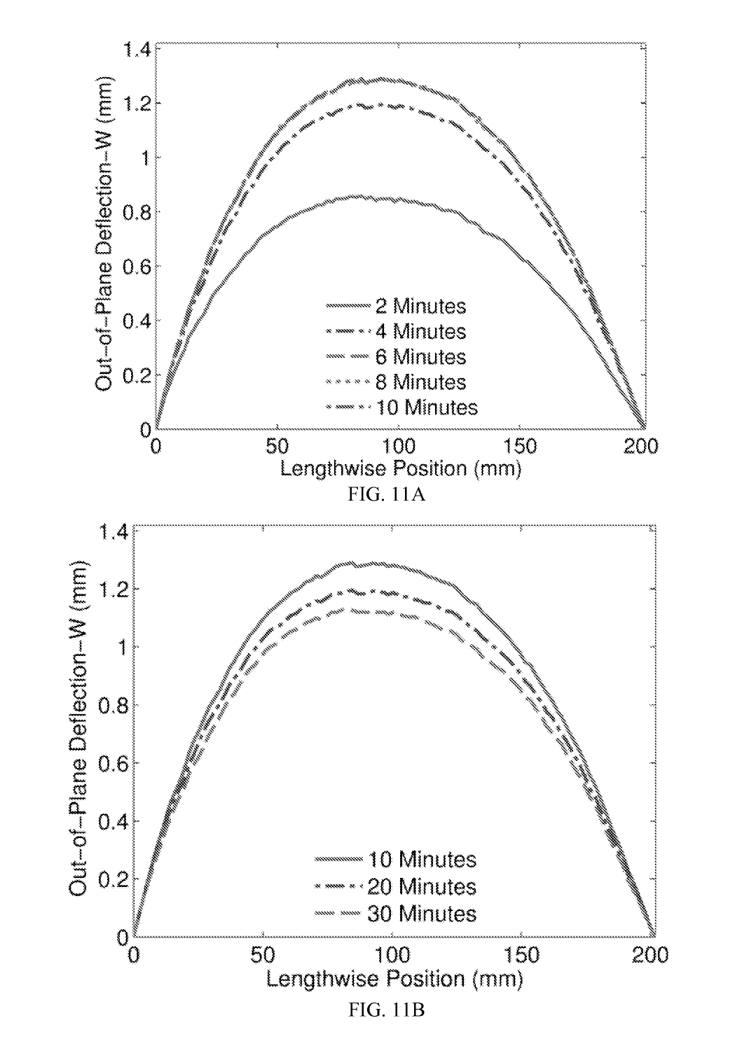

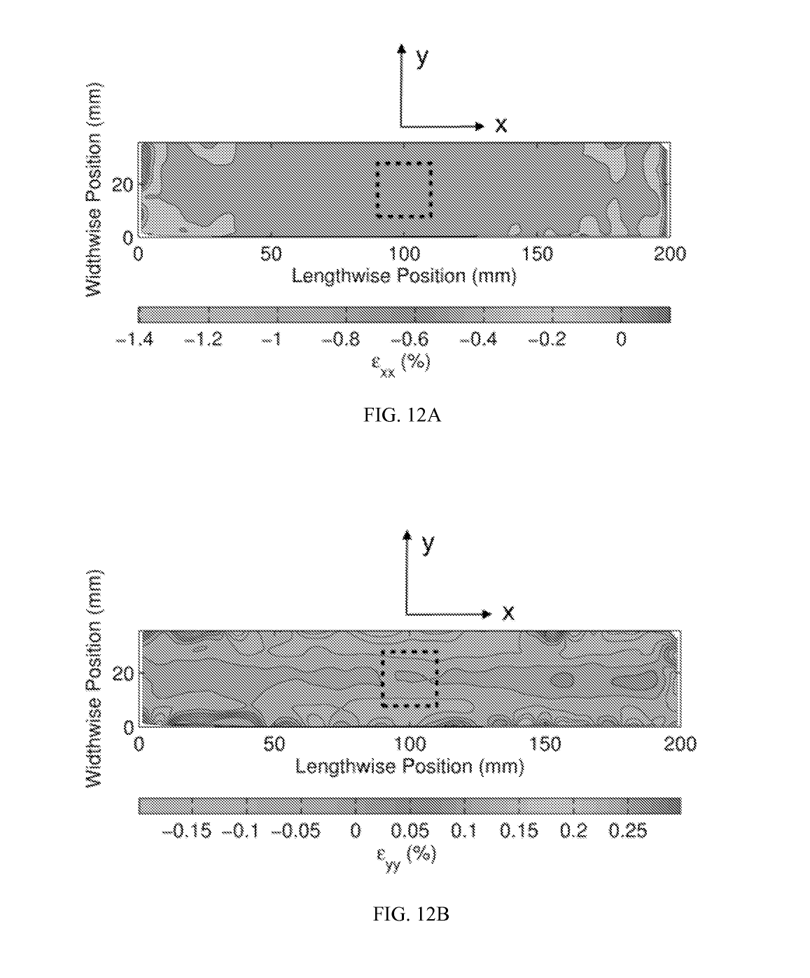

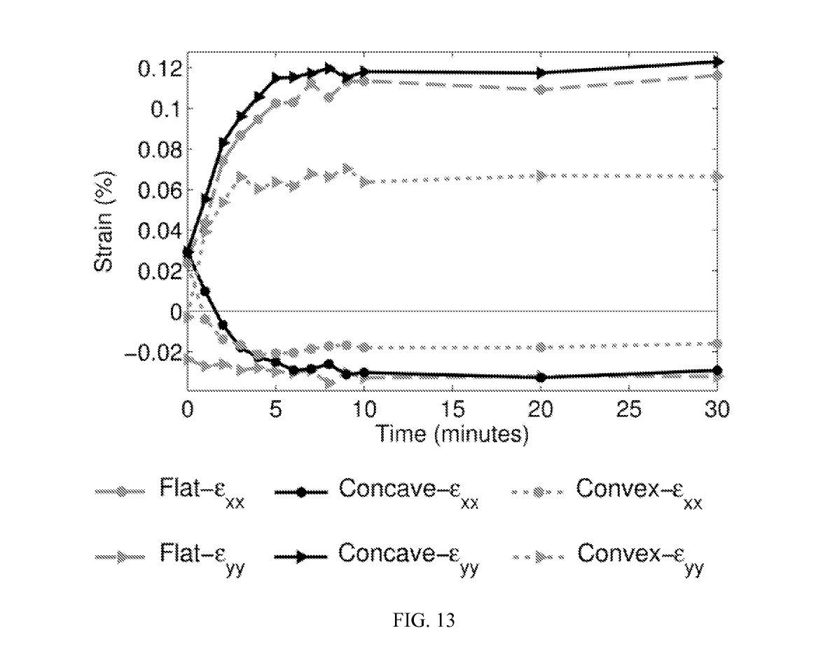

Table 2, below, shows the maximum out-of-plane deflection for flat and curved samples. FIGS. 9 and 10 show plots of centerline deformation along the longitudinal direction for UCAs through thirty minutes. The data clearly show that the concave sample has significantly less residual deformation than the flat sample over the thirty minute trial. The concave sample has a maximum variation from the original sample of only 0.35 mm while the flat sample has a maximum difference of 12.7 mm. The convex sample deflected a maximum of 1.29 mm in the same time period. The graphs show that the concave UCA reaches a peak deflection at approximately six minutes then relaxes a distance of 60 μm by the thirty minute mark. The flat UCA does not reach equilibrium in thirty minutes as it continues to deflect until the thirty minute mark. The convex UCA behaved similarly to the concave sample. However, the data show that a majority of the deformation has already occurred after six minutes, which was also true of the concave sample.

TABLE 2
Maximum deflection for the UCA samples at each marked time

| | Max Deflection | Max Deflection |
|---|---|---|
| | Concave Sample | Flat Sample |
| Time | (recovered-reference) | (recovered-reference) |
| Reference | 0.00 mm | 0.00 mm |
| 2 min | 0.28 mm | 5.89 mm |
| 4 min | 0.34 mm | 9.80 mm |
| 6 min | 0.36 mm | 11.4 mm |
| 8 min | 0.35 mm | 12.0 mm |
| 10 min | 0.35 mm | 12.1 mm |
| 20 min | 0.31 mm | 12.3 mm |
| 30 min | 0.30 mm | 12.7 mm |

Preliminary tests clearly show transverse curvature of a unimorph substrate substantially improves shape recovery of the UCAs. Additional curved UCAs were prepared with concave orientation (saddle configuration) and with convex orientation (trough configuration). The convex sample was constructed to determine the effect on the residual deformation in an alternate orientation. The convex UCAs were monitored via DIC for thirty minutes during the cool down, as had been the UCAs. Table 3, below, shows maximum out-of-plane deviation with respect to time for the convex sample versus the original concave sample. The concave sample deflects only 0.36 mm, whereas the convex sample deflects 1.29 mm in the same time period. The convex sample behaves similarly to the concave sample with respect to relaxation. Both samples reach maximum deflection in approximately six minutes and decrease in deflection somewhat up to the thirty minutes. FIG. 11 plots the centerline deformations for the convex sample. Results indicate that concave UCAs show minimal deflections under comparable conditions. The data shows that a majority of the deformation had already occurred after six minutes for all samples tested. The data matches the temperature profile results seen during the thermocouple experiments as the majority of cooling occurred in the first six minutes. After ten minutes the substrate and SMP outer surfaces arc at ambient temperature; however the inner surfaces of the SMP had not reached room temperature due to the thickness differences between the substrate and SMP. The SMP continued to cool and contract from its heated state which explains the continued deflection seen in the flat UCA. The non-monotonic behavior seen in the curved UCAs is explained similarly. The carbon fiber has a CTE that is two orders of magnitude below that of the Veriflex® SMP resulting in a contraction of the SMP at a much higher rate than the carbon fiber substrate as the UCA cools. However, after both the UCA and SMP have cooled for approximately ten minutes, contracting past the stability point of the UCA, the increased bending stiffness of the transversely curved substrate compensates for this mismatch in CTEs resulting in a slow relaxation to the equilibrium point. This results in a decreased residual deflection unlike the flat UCA, which isn't assisted by increased bending stiffness in the substrate.

TABLE 3
Maximum deflection for the UCA samples at each marked time

| | Max Deflection | |
|---|---|---|
| | Concave Sample | Max Deflection |
| | (recovered- | Convex Sample |
| Time | reference) | (recovered-reference) |
| Reference | 0.00 mm | 0.00 mm |
| 2 min | 0.28 mm | 0.86 mm |
| 4 min | 0.34 mm | 1.19 mm |
| 6 min | 0.36 mm | 1.29 mm |
| 8 min | 0.35 mm | 1.29 mm |
| 10 min | 0.35 mm | 1.29 mm |
| 20 min | 0.31 mm | 1.20 mm |
| 30 min | 0.30 mm | 1.13 mm |

Testing was carried out with additional concave curved UCAs to determine the repeatability of testing results and any residual deformation as additional deflection cycles were performed on UCAs. A series of four consecutive tests were conducted and compared at the maximum out-of-plane position (Z+W) time of six minutes, as well as at the end of the data collection period. Table 4, below, shows that there is high reproducibility of the UCAs, where the data range varied 40 μm at six minutes and 30 μm at 60 minutes.

TABLE 4
Repeatability test data for the concave curved UCA sample

| | | | | | | Coefficient |
|---|---|---|---|---|---|---|
| | Test 1 | Test 2 | Test 3 | Test 4 | Standard | of |
| Time | Position | Position | Position | Position | Deviation | Variation |
| 6 min | 1.93 | 1.95 | 1.91 | 1.93 | 1.6E−2 mm | 0.85% |
| | mm | mm | mm | mm | | |
| 60 min | 1.81 | 1.80 | 1.78 | 1.81 | 1.4E−2 mm | 0.78% |
| | mm | mm | mm | mm | | |

The preceding tests clearly show that the concept of applying transverse curvature to a unimorph substrate substantially improved shape recovery. After determining the maximum out-of-plane deflections and their relation to transverse curvature the DIC data acquired was also used to view strain fields as the UCAs cooled. The strain fields were found to be fairly uniform for all samples so the center section of each UCA was selected as the area of interest, evaluated and averaged to get an average strain value at specific times during the cooling cycle. The area of interest is exhibited in the area inside of the dashed lines. The averaged values from the area of interest are shown where it was again confirmed that a majority of the deformation occurs in the first six minutes. All of the strains at thirty minutes are less than approximately 0.12% at the center of the UCA with the highest strains seen in the transverse direction of the concave UCA followed closely by flat UCA in the longitudinal direction.

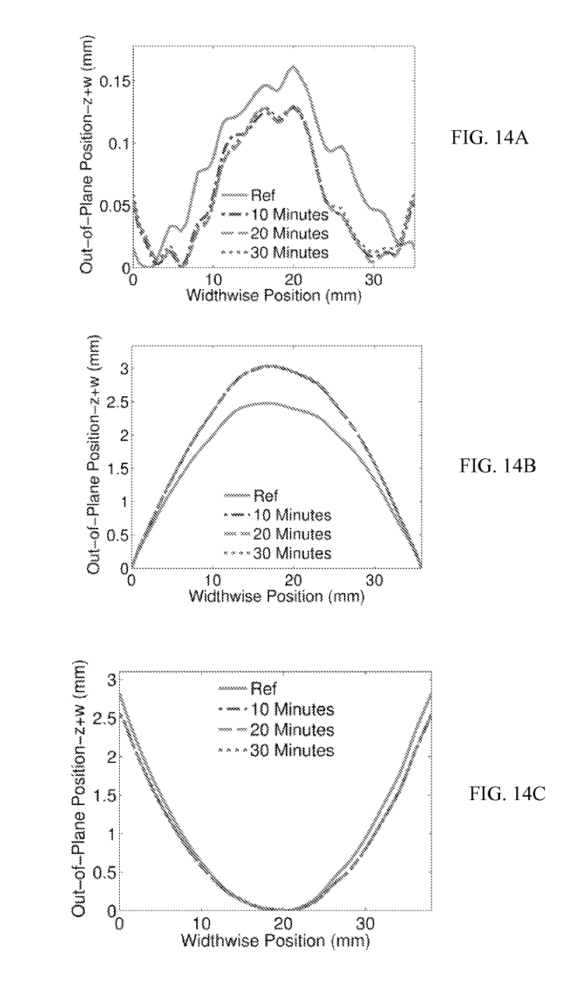

Also extracted from the DIC data for the deployed configuration was the transverse direction out-of-plane position. This data was processed in the same manner as the out-of-plane deformation; however it was taken at the center of the UCA perpendicular to the lengthwise direction. FIG. 14 displays the out-of-plane position, the original location (z) plus out-of-plane deformation (w), for each of the three UCAs. The flat UCA had almost no change in its widthwise position after a thermo-mechanical cycle while the concave UCA actually increased in transverse curvature providing greater bending stiffness than the original UCA. The concave UCA increased in height by approximately 0.5 mm after thirty minutes, which is a 20% increase in the curvature. The convex UCA actually relaxed and decreased in transverse curvature after thirty minutes. This decrease in transverse curvature contributed to the convex UCA performing worse than the concave UCA despite having the same initial radius of curvature.

Additional tests were performed on a second concave curved sample to determine the repeatability of testing results and if additional residual deformation occurred when additional thermo-mechanical cycles were performed on the UCA. A series of four consecutive tests were conducted and compared at the maximum out-of-plane position (z+w) at six minutes as well as at the end of the data collection time.

Table 5 shows the data varied by only 40 μm at six minutes and 30 μm at 60 minutes, which are acceptable ranges for repeatability.

TABLE 5
Repeatability of testing data for the concave UCA sample

Time

| | 6 min | 60 min |
|---|---|---|
| Trial 1 Positions | 1.93 mm | 1.81 mm |
| Trial 2 Positions | 1.95 mm | 1.80 mm |
| Trial 3 Positions | 1.91 mm | 1.78 mm |
| Trial 4 Positions | 1.93 mm | 1.81 mm |
| St. Dev. | 16 μm | 14 μm |
| CV | 0.85% | 0.78% |

Deformed/Stored Configuration Results

In addition to determining the characteristics of UCAs in the deployed configuration, Step 7 of FIG. 2, multiple analyses were conducted on the deformed/stored configuration, Step 4 of FIG. 2. For complete understanding of the thermo-mechanical cycle, the strains in the stored configuration and out-of-plane deformation in the y-direction were investigated. The deformed configuration is the state in which the UCA undergoes its maximum deformation and is crucial to determine if a UCA is still in the elastic range of deformation when stored. At a [±45°] configuration, carbon fiber is capable of enduring high strains with minimal residual deformation when stored in a cylindrical configuration. Similar to the original/programmed state, the cooling profile after the initial hour soak at 85° C. was established with five thermo-mechanical trials. The cooling profile closely resembled the deployed configuration profile as the UCA cools from 65° C. to 25° C. in the first six minutes, then reaches ambient temperature on the surface at approximately ten minutes. The difference in initial cooling temperatures, 75° C. for deployed vs. 65° C. for stored, is attributed to the time it took to mechanically deform the UCA after removing it from the environmental chamber for the stored configuration whereas the deployed configuration required no mechanical deformation.

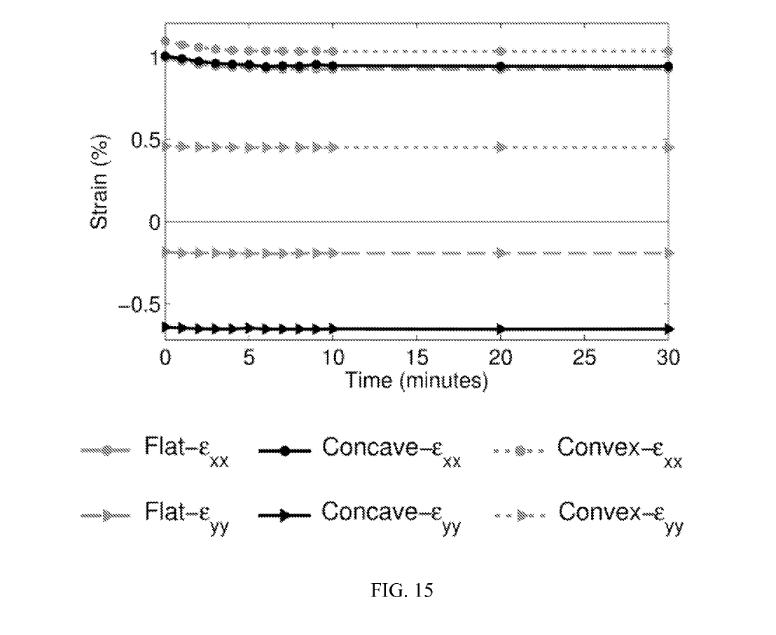

After determining the cooling profile in the stored configuration, the DIC data acquired in the stored configuration was evaluated for the strain fields during cooling and out-of-plane position of the three types of UCAs. FIG. 15 shows the average strain on the selected surface area of the UCAs, identical to the area on the deployed UCAs, during the storage cool down. The strain fields were found to be fairly uniform with a slight decrease in the strain in the longitudinal or x-direction due to cooling during the first six minutes. Once the samples had passed this point the strains appeared to be constant until the storage cooling cycle ended. The mechanical strain from bending the UCA into the stored configuration was approximately 1% while the thermal strain was on the order of 0.1%. The maximum strains seen were approximately +1.15% and −0.65% occurring in the flat UCAs x-direction and concave UCAs y-direction respectively. These strain values were determined to be still within the elastic region for [±45] oriented carbon fiber.

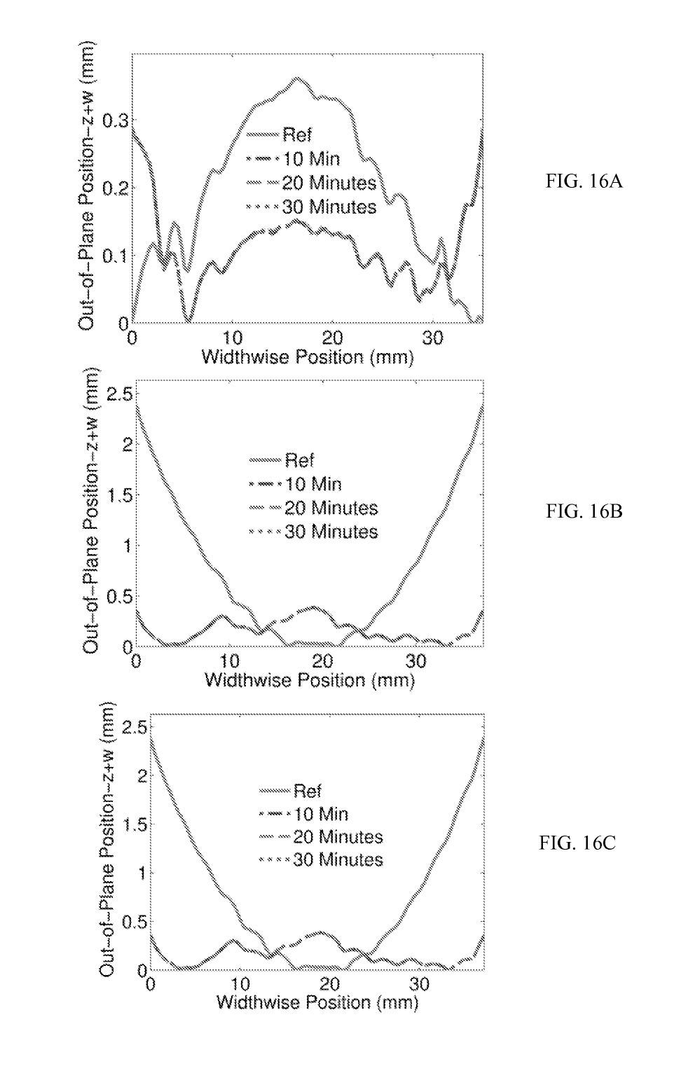

The out-of-plane deformation in the transverse direction was extracted from the DIC data to determine the effect of transverse curvature in the stored configuration. This data was processed in the same manner as the out-of-plane deformation; however, as stated previously, it was taken at the center of the UCA perpendicular to the lengthwise direction. FIG. 16 displays the out-of-plane position for each of the three UCAs in the stored configuration. All three of the UCAs showed clearly defined reference shapes but, once placed in the storage container, all have negligible transverse curvature. Each UCA had an out-of-plane position of less than 0.4 mm when in the stored position. The data shows that in the stored condition all three UCAs have nearly identical out-of-plane flattened shapes.

### Expanded Design Space Investigation

The concave curved UCA was tested and compared to the baseline flat UCA in the expanded design space, but the convex curved UCA was not tested as it performed an order of magnitude worse than the concave UCA despite having the same amount of transverse curvature. As illustrated in FIG. 5, there are five variables of significance: actuator length, substrate radius of curvature, substrate width, SMP width, and SMP thickness. Two of the variables are eliminated, as the SMP width and actuator length is fixed. Substrate radius of curvature, SMP thickness, and substrate width were altered during the expanded design space investigation. Three transverse curvatures were investigated and designated as: flat (infinite radius of curvature); low transverse curvature (127 mm radius of curvature); and high transverse curvature (63.5 mm radius of curvature). SMP thicknesses were thin (0.8 mm) and thick (1.6 mm). Substrate widths were narrow (25.4 mm), intermediate (38.1 mm), and wide (50.8 mm).

Table 6 shows the different curvatures, thicknesses, and widths examined and their respective designations.

TABLE 6
Radius of curvature (ρ), SMP thickness (t) and substrate width (s)
possibilities and their respective designations for the UCAs
Nomenclature and Supporting Values

| | | | |
|---|---|---|---|
| Transverse Curvature | Flat | Low | High |
| Radius of Curvature (ρ) | ∞ | 127 mm | 63.5 mm |
| SMP Thickness (t) | Thin | Thick | — |
| Thickness Values | 0.8 mm | 1.6 mm | — |
| Substrate Width (s) | Narrow | Intermediate | Wide |
| Width Values | 25.4 mm | 38.1 mm | 50.8 mm |

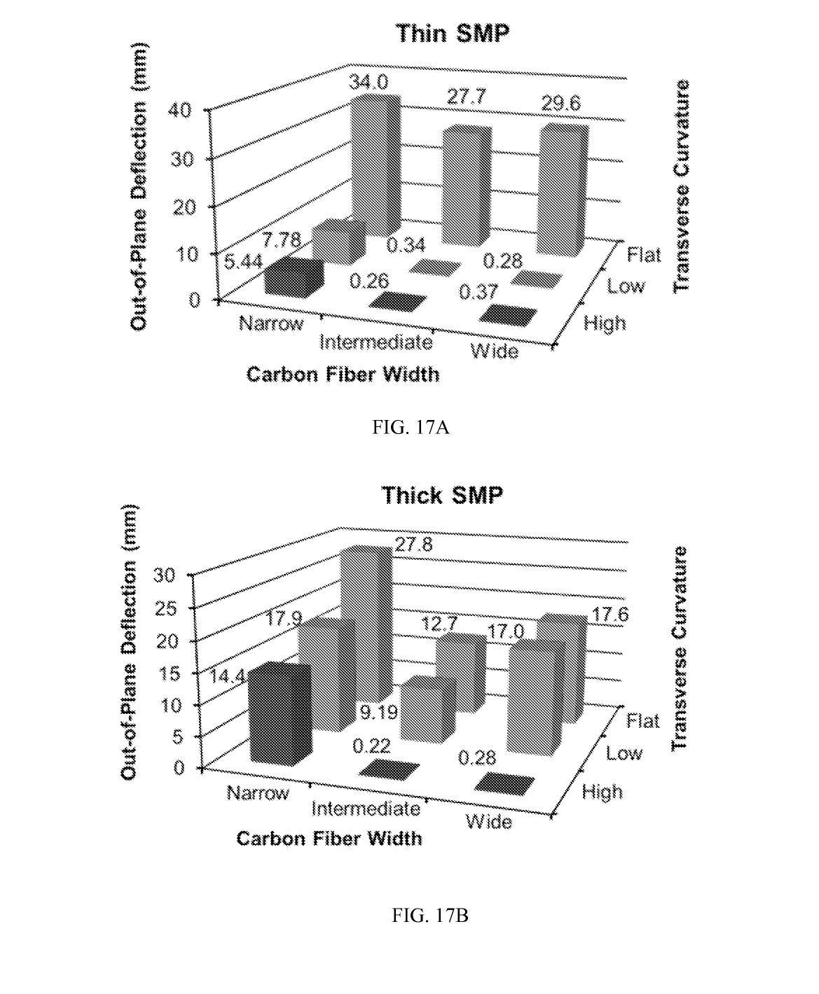

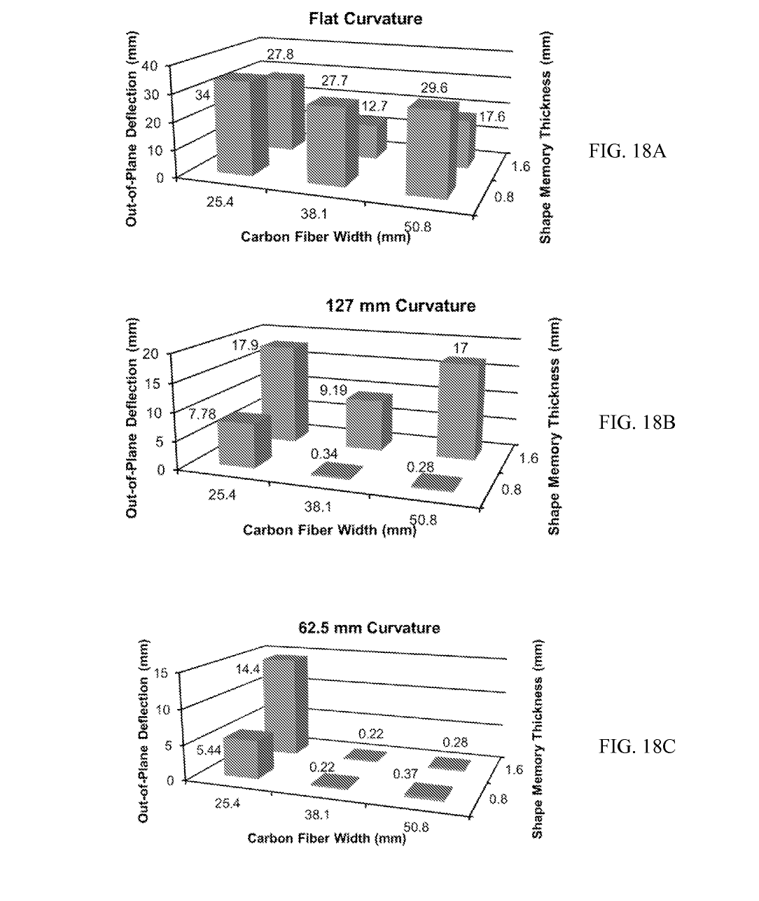

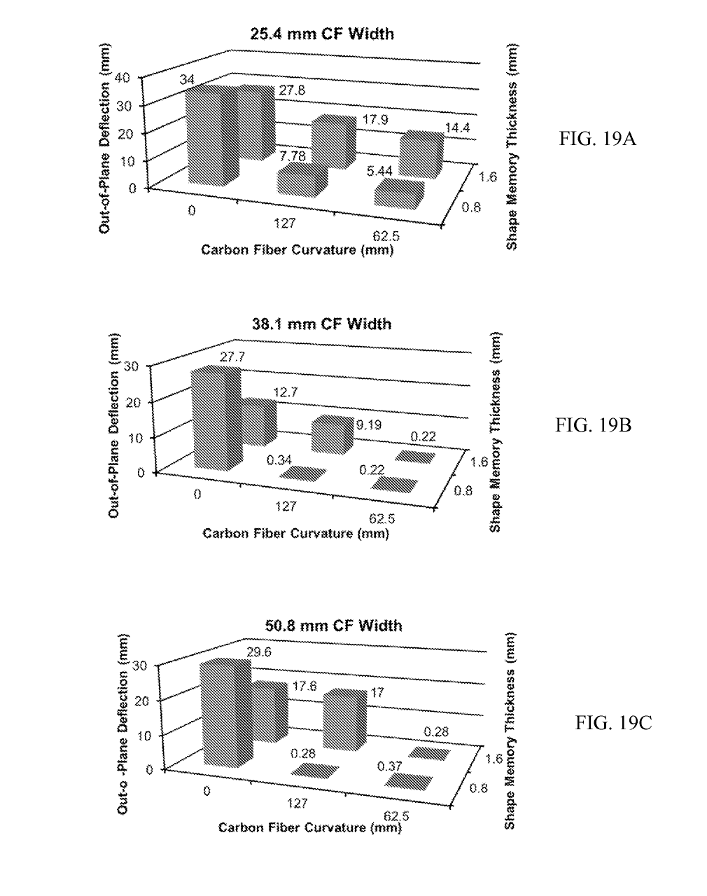

All samples were tested for a minimum of three thermo-mechanical cycles and the data was analyzed and the maximum out-of-plane deflection was calculated for each UCA. The flat and high transverse curvature samples with thick SMP and intermediate substrate width, were identical to the flat and concave samples tested previously. All previously tested samples were tested for a minimum of three thermomechanical cycles and the maximum out-of-plane deflection was calculated for each UCA, and is tabulated in Table 7, below, and plotted as bar charts in FIGS. 18, and 19 and where the out-of-plane deflection varying the UCA width and SMP thickness the results were identical with those of FIG. 17. The bar charts clearly indicate that curvature had a major effect on the recoverability. The larger the smaller radius of curvature, the less permanent deformation was observed. In general, a wider carbon fiber epoxy composite substrate (UCA width) modestly aided recoverability, and thicker SMPs decreased recoverability. In Table 7, samples are indicated ###_##_###, where the first three digits relate to the radius of curvature of the carbon fiber epoxy composite in mm or mm×10, the second two digits are the SMP thickness in mm×10, and the last three digits are the UCA width in mm×10. Flat samples have an undefined radius of curvature and are indexed as 000.

TABLE 7
Maximum deflection at the end of the 60 minute observation period

| | | | Max | | Max |
|---|---|---|---|---|---|
| | Max Deflection | | Deflection | | Deflection |
| Sample | (mm) | Sample | (mm) | Sample | (mm) |
| 000_08_254 | 34.0 | 127_08_254 | 7.78 | 635_08_254 | 5.44 |
| 000_08_381 | 27.7 | 127_08_381 | 0.34 | 635_08_381 | 0.22 |
| 000_08_508 | 29.6 | 127_08_508 | 0.28 | 635_08_508 | 0.37 |
| 000_16_254 | 27.8 | 127_16_254 | 17.9 | 635_16_254 | 14.4 |
| 000_16_381 | 12.7 | 127_16_381 | 9.19 | 635_16_381 | 0.22 |
| 000_16_508 | 17.6 | 127_16_508 | 17.0 | 635_16_508 | 0.28 |

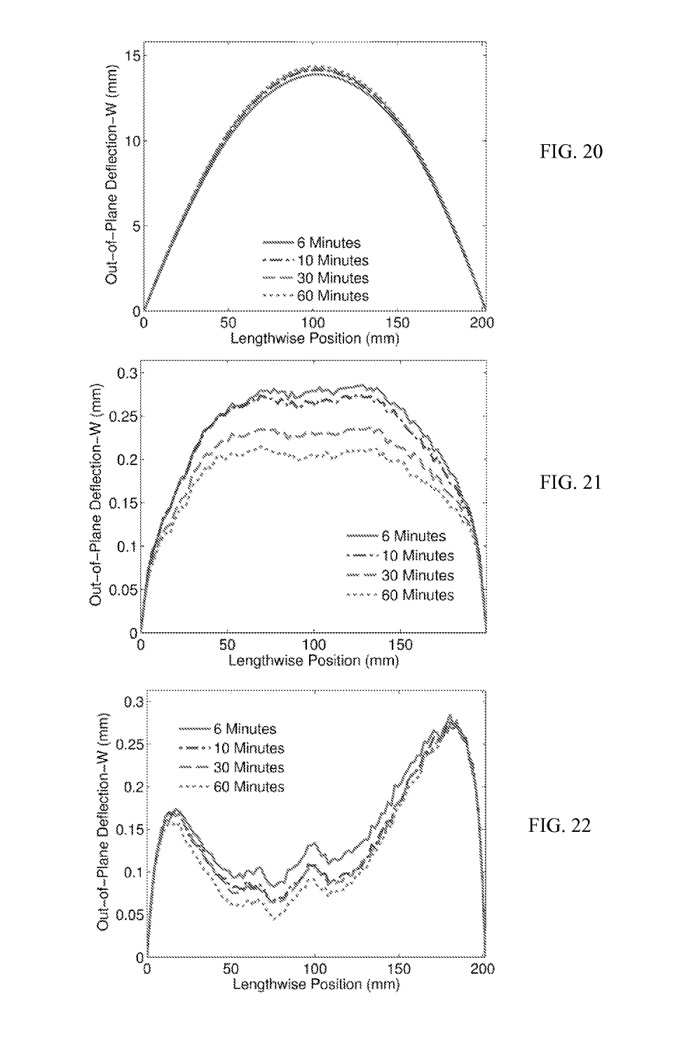

As the UCA's curvature increases, the amount of residual deformation decreases dramatically. For example, the out-of-plane deflection decreases from 27.7 mm for the flat 38.1 mm wide samples to 0.34 mm and 0.22 mm for the 127 and 63.5 mm radius of curvature samples, respectively. Deflection decreases as the UCA's width increases from 25.4 to 38.1 mm. Increasing the UCA's width from 38.1 to 50.8 mm does not decrease the deflection as markedly as the increase in width from 25.4 to 38.1 mm, and in some cases, increases the deflection. The trend of maximum deflection of the UCA's width is shown in FIGS. 20, 21, and 22 for 63.5 mm radius of curvature samples. Noted outliers to the data are the 000_16_508 and 127_16_508 samples, whose deflections were greater than that of the smaller UCA width samples 000_16_381 and 127_16_381. The behavior of these outliers was due to the combination of the UCA width and curvature. When progressing from a stored state to the original undeformed state, the carbon fiber epoxy composite support achieves an equilibrium point where the curvature in the widthwise direction is nearly flat. Most samples easily snap through this state and return to the original shape. However, for sample 127_16_508 this point acted as a point of instability and resulted in elevated residual deformation compared to that seen in the other UCA sets. This equilibrium point is also seen in sample 000_16_508 as the residual deformation is nearly identical due to the combination of UCA width and lack of transverse curvature.

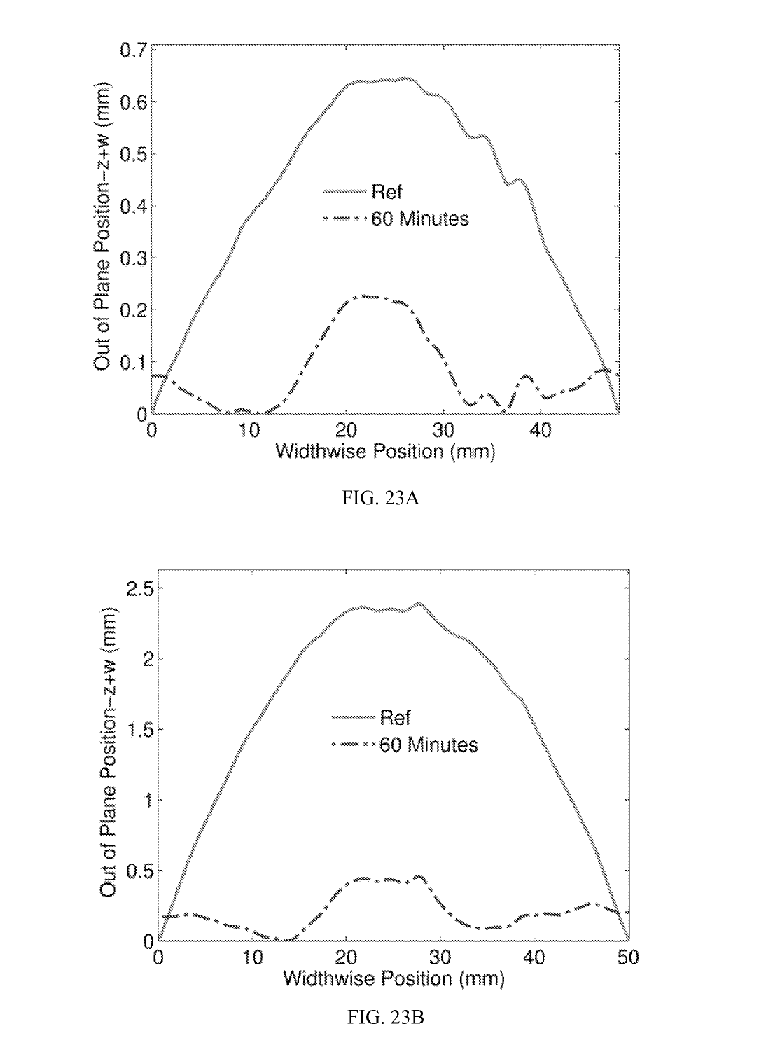

When progressing from the stored state, Step 4 of FIG. 2, to the deployed state, Step 7, of FIG. 2, the carbon fiber achieve an equilibrium point where the transverse curvature in the widthwise direction is nearly flat. Most samples can easily snap through this middle state due to the transverse curvature in the substrate and return to the deployed shape. However, for the low transverse curvature sample with thick SMP and a wide substrate this point acted as an unstable equilibrium point between two stable equilibria and thus resulted in elevated residual deformation compared to that seen in the other UCA sets. This equilibrium point was also seen in the flat sample with thick SMP and wide substrate as the residual deformation was nearly identical due to the combination of CF width and lack of transverse curvature. This is illustrated in FIG. 23 which shows the out-of-plane position (z+w) of the reference transverse curvature versus the curvature after a thermo-mechanical cycle. The graphs show that the flat, wide substrate, thick SMP UCA and the low transverse curvature, wide substrate, thick SMP UCA had similar maximum out-of-plane positions in the transverse direction and out-of-plane deformation in the longitudinal direction after a thermo-mechanical cycle further establishing that this is an unstable equilibrium point between the stored and deployed states of the UCA.

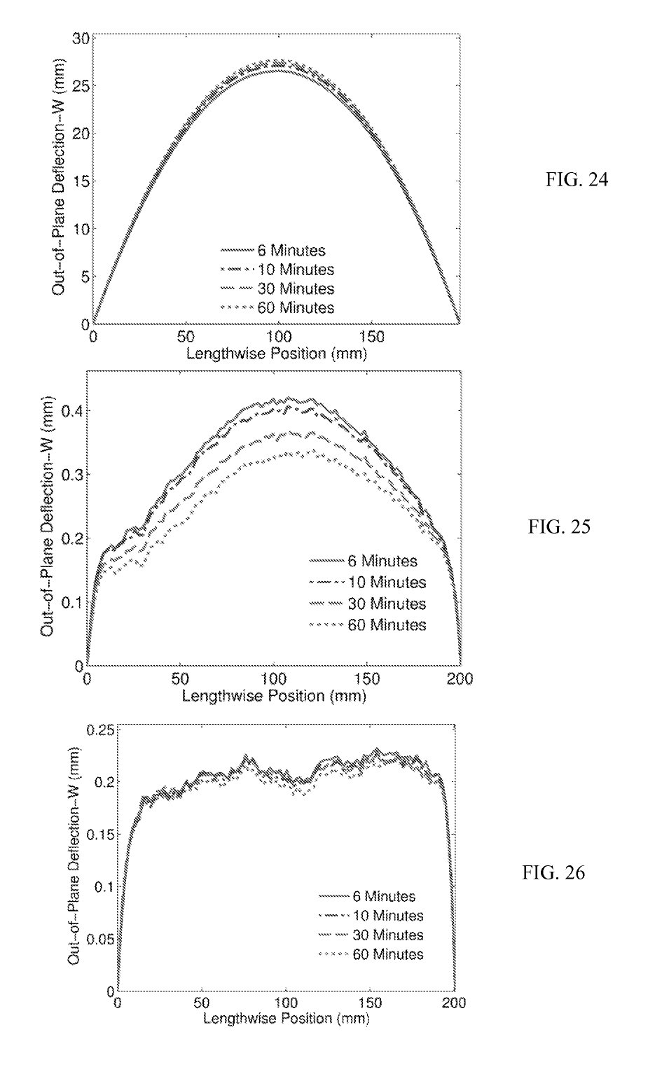

An increase in curvature significantly reduces residual deflection and greater recovery of the UCA. The flat sample 000_08_381 has a maximum deflection of 27.7 mm, while increasing the curvature to the 127 mm sample decreases maximum deflection by two orders of magnitude to 0.34 mm. The trend of maximum deflection versus increasing curvature is shown in FIGS. 24, 25, and 26 for constant SMP thickness and UCA width. Hence, an increase in curvature allows greater recovery of the UCA and reduces residual deflection in UCAs.

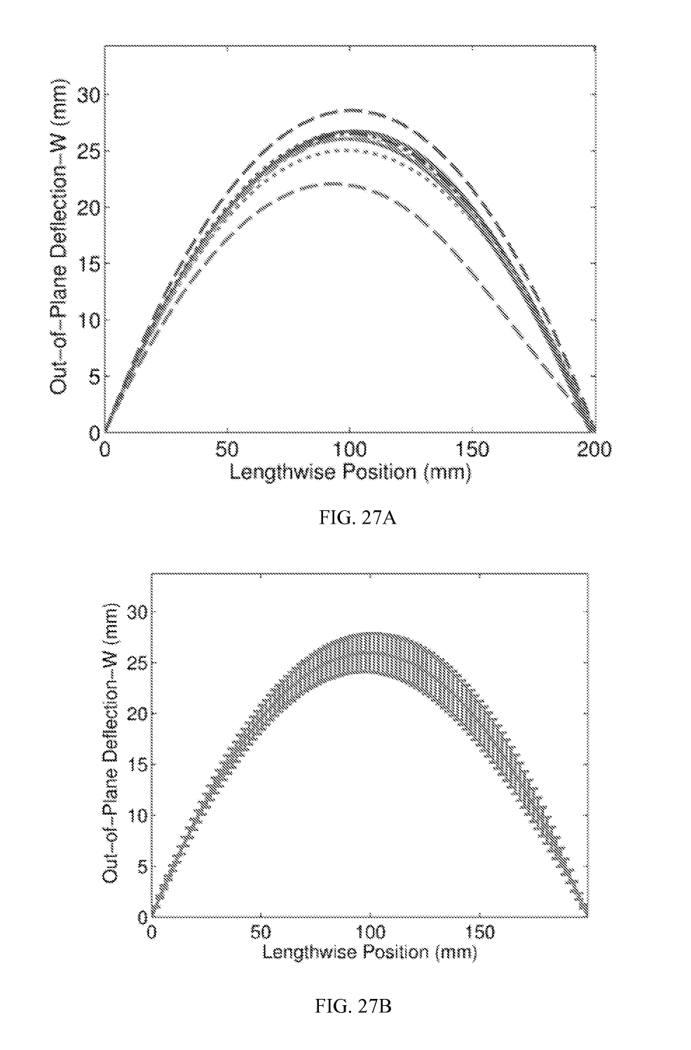

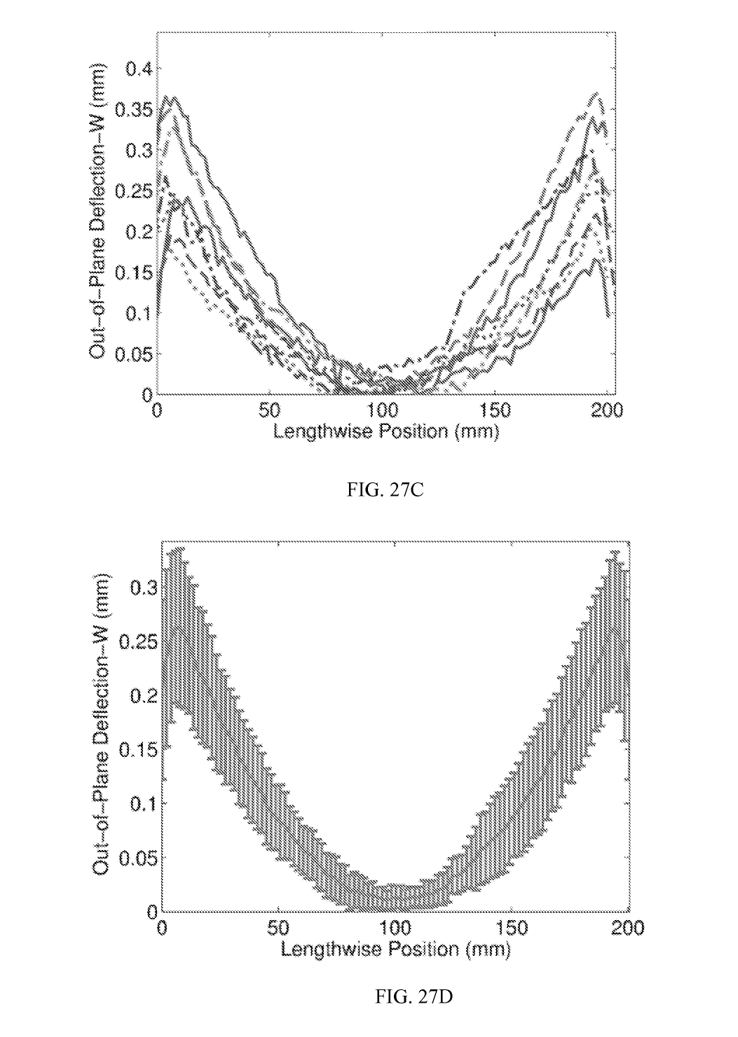

Eight 000_08_381 samples and eight 625_08_381 samples were tested to determine the out-of-plane deflection ranges for the UCAs and determine the statistical significance of curvature on the measured deflection. FIG. 27 shows the eight out-of-plane deflections for both samples as well as the standard deviation of those samples. These tests show that the maximum standard deviation for the 000_08_381 sample was ±2.2 mm with a mean out-of-plane deflection of 26 mm. The maximum standard deviation for sample 625_08_381 was ±0.1 mm with an average out-of-plane deflection of 0.26 mm. These results show a statistically significant difference in the out-of-plane deflection as curvature increases. Extrapolating this data to other test cases indicates that changes in carbon fiber epoxy composite width and curvature must be evaluated on a case-by-case basis. In addition to testing the high radius of curvature and flat UCAs, a single [±45°] layer of intermediate width carbon fiber of each radius of curvature underwent a thermo-mechanical cycle. The purpose was to determine the out-of-plane deflection of just the CF component to the UCA and find its contribution to the total UCA deflection.

Experiments were conducted to record the deflection angle (°) for use to determine the shape fixity or shape retention loss of the stored UCA specimens over time. Ideally, a programmed UCA would be heated above T_{g}, mechanically deformed into the stored configuration, cooled below T_{g}, and would be capable of holding the desired stored shape indefinitely without shape retention loss and have deflection angle less than or equal to zero.

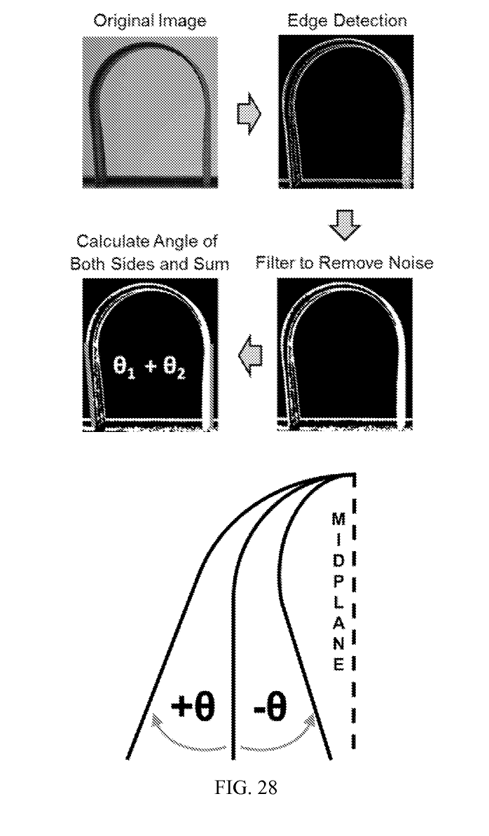

Post-processing of UCA images were required to determine the deflection angle for each UCA over time. Post-processing was accomplished via MATLAB where each image was evaluated with an edge detection algorithm to find the boundaries of the UCA. The image was then filtered to eliminate any white noise the edge detection procedure incorrectly interpreted as a boundary of the UCA. Finally, the image was evaluated on both sides to find the angle of the outer edges of the UCA. This was accomplished by plotting lines along the outer edges of the UCA and finding the angle of each side with respect to a vertical line at the mid-plane. Positive deflection was recognized as angles returning the UCA back to the original/programmed state and negative deflection as angles further establishing the UCA in a stored configuration. A deflection angle of zero would correspond to UCAs that retained the U-shaped stored configuration without any relaxation or contraction. This process is illustrated in FIG. 28(a) while the deflection angles are shown in FIG. 28(b).

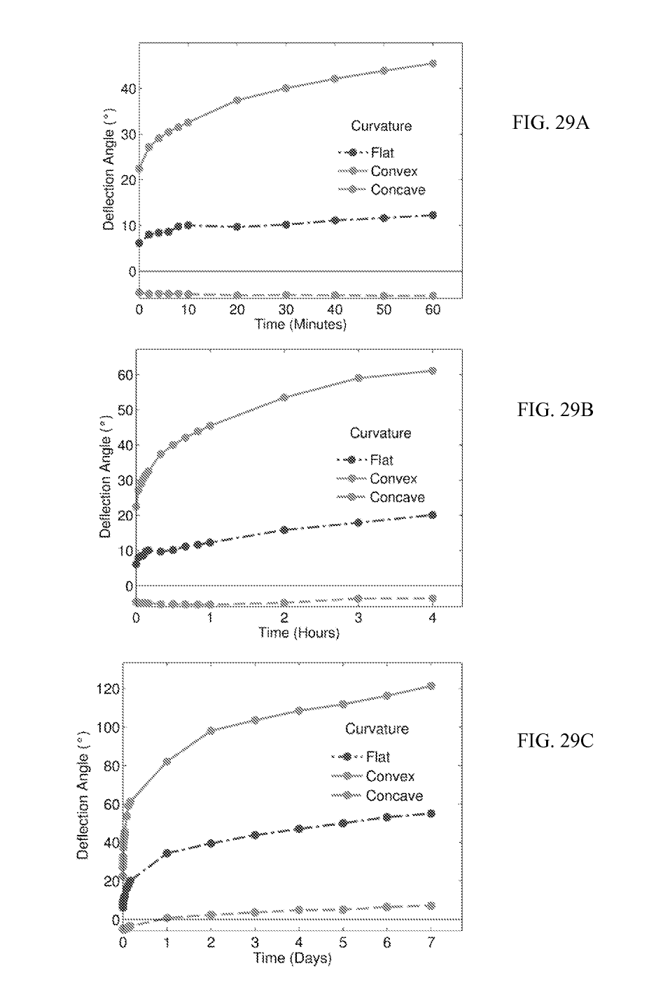

Data for the flat, concave, and convex UCA samples were collected at various intervals to establish a pattern of relaxation or contraction in the stored configuration. Initial testing determined that the deflection angle of the UCAs displayed asymptotic behavior and thus images over several time scales were needed. The deflection angle versus time for the first hour, over four hours, and over seven days is shown in FIG. 29. The experiments were terminated after seven days as general trends could be established and a majority of the UCA relaxation had already occurred. The data clearly shows all UCAs have positive deflection angles after seven days but only the concave sample has displayed acceptable fixity behavior. The concave sample initially has a deflection angle of −4.6° after being removed from the fixity holder and after sixty minutes had contracted slightly to an angle of −5.4°. The concave sample had a significantly lower deflection angle compared to the convex sample's initial deflection angle of 22.5° which expanded to 45.5° after sixty minutes. After four hours the concave sample experiences some relaxation and has an angle of −3.6° while the flat and convex samples continue to have increasingly large deflection angles of 20.1° and 61.1° respectively. Finally, after seven days the concave sample had a deflection angle of 7.1° while the flat and convex samples had angles of 55.0° and 121.4° respectively. The concave UCA displays a nearly flat growth rate with movement of less than a degree per day. The flat sample's deflection angle continued to increase at a rate of three degrees per day while the convex sample expands at five degrees per day.

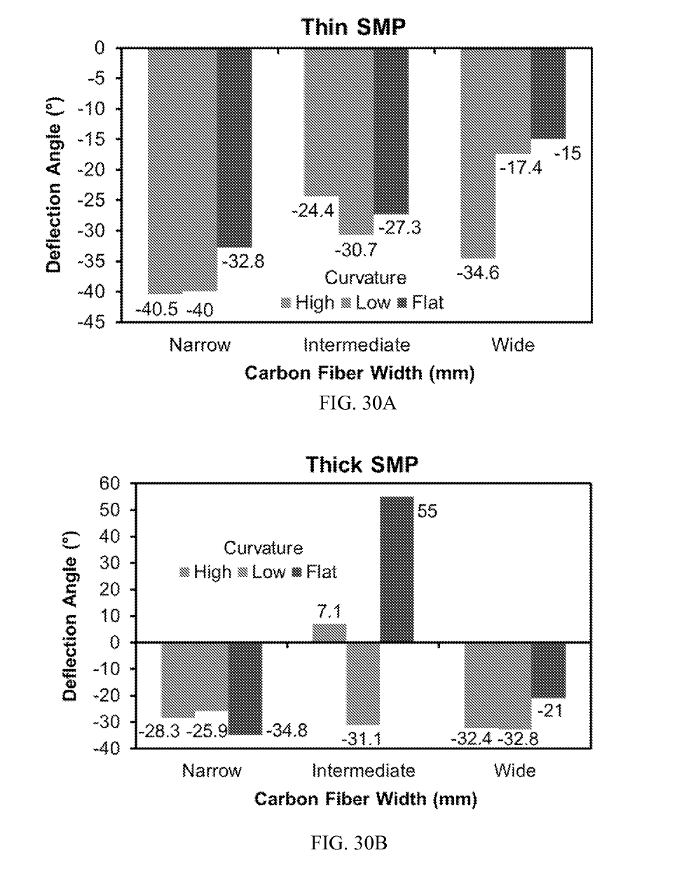

The preliminary tests on concave UCAs showed that applying concave transverse curvature to a unimorph substrate did not substantially hinder the shape fixity of the UCA. The tests show that a UCA with concave transverse curvature tends to have less shape retention loss than flat UCAs with all other parameters identical. For the UCAs of Table 6, decreasing SMP thickness tends to decrease the deflection angle and allow the UCA to contract further into the stored configuration, as shown in FIG. 30. This trait is pronounced for the narrow substrate widths as the UCAs with transverse curvature see a 12-14° decrease in deflection angle with all other parameters held constant. As the substrate width narrows in the thin SMP samples the deflection angle decreases. This effect is diminished in the thicker SMP as most of the samples are in the 25-35° range. Definite trends with respect to substrate curvature cannot be seen with the data available as each substrate width and corresponding SMP thickness data set appears to perform differently. However, a negative deflection angle is a favorable result as it shows that transverse curvature in the substrate does not negatively affect shape fixity and cause an excessive amount of shape retention loss.

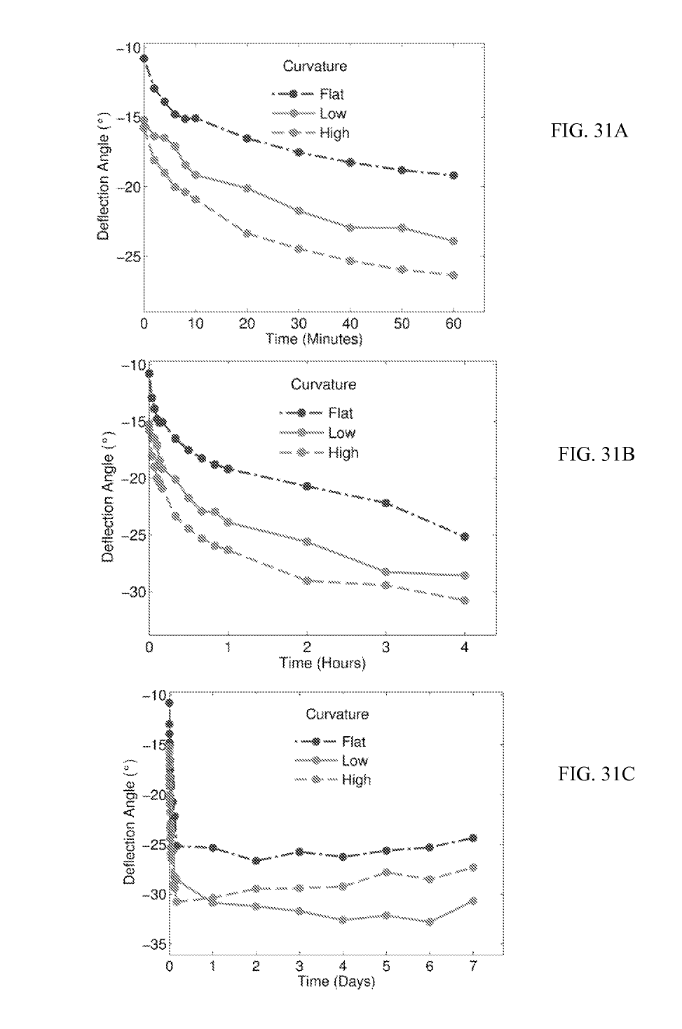

The development of deflection angle versus time for the thin SMP, intermediate substrate UCAs, with flat, low, and high transverse curvatures is shown in FIG. 31. Analysis of this data shows that the UCAs contract rapidly over the first four hours and then reach an approximate equilibrium. All samples contract approximately 10° over the first sixty minutes and a total of 15° after the four hours. After a day, all samples maintain nearly constant deflection angles though the seventh day. Misalignment errors attributed to an uncertainty of approximately ±0.5° in the data. The results indicate that most of the UCAs reach equilibrium after the first day with the exception of the flat and high curvature UCAs with thick SMP and intermediate substrate width.

It should be understood that the examples and embodiments described herein are for illustrative purposes only and that various modifications or changes in light thereof will be suggested to persons skilled in the art and are to be included within the spirit and purview of this application.

We claim:

1. A unimorph composite actuator (UCA), comprising a deformable substrate having a lateral curvature relative to an axis or curve of the substrate and at least one shape memory material (SMM) attached to at least a portion of a face of the substrate.

2. The UCA of claim 1, wherein the substrate is a thermoplastic, a thermoset, a thermoplastic composite, a thermoset composite, or a metal.

3. The UCA of claim 1, wherein the SMM is a shape memory polymer (SMP).

4. The UCA of claim 3, wherein the SMP is: (I) a chemically cross-linked glassy thermoset; (II) a chemically cross-linked semi-crystalline rubber; (III) a physically cross-linked thermoplastic; or (IV) a physically cross-linked block copolymer.

5. The UCA of claim 3, wherein the SMP is: P(MMA-co-VP)-PEG semi-IPN; copolyester; P(AA-co-MMA)-PEG; PMMA-PBMA copolymer; PET-PEG copolymer; P(MA-co-MMA)-PEG; Soybean oil copolymer with styrene and DVB; styrene copolymer; thermosetting PU (water swollen); thermosetting PU (ester type); dehydrochlorinated cross-linked PVC; polynorbornene; ultrahigh MW PMMA; Poly-caprolactone; EVA+nitrile rubber; PE, Poly-cyclooctene; PCO-CPE blend; PCL-BA copolymer; Poly(ODVE)-co-BA; EVA+CSM; POSS telechelic; PLAGC multiblock copolymer; Aramid/PCL; PVDF/PVAc Blend; Poly(ketone-co-alcohol); PCL-b-ODX; PLA/PVAc blend; Poly(l-hexadecene)-co-PP; PE-co-PMCP; POSS-PN block copolymers; PA-PCL Polyamides; PET-co-PEO; PE-co-Nylon 6; PS-TPB; POSS/PDLA-co-PCL/MDI; 4,4′-Dihydroxybiphenyl (DHBP)/PCL blend with phenoxy resin or PVC/Hexamethylene diisocyanate (HDI); 1,6-HD/HDI-1,2-BD/4,4′-MDI; 1,4-Butanediol/Poly(ethylene adipate)/MDI; 1,4-Butane glycol, ethylene glycol, bis(2-hydroxyethyl) hydroquinone, bisphenol A+ethylene oxide, and/or bisphenol A+propylene oxide/Polypropylene glycol, 1,4-butaneglycol adipate, polytetramethylene glycol, polyethylene glycol, and/or bisphenol A+propylene oxide/2,4-Toluene diisocyanate, 4,4′-diphenyl-methane diisocyanate, and/or hexamethylene diisocyanate; 1,4-BD/Poly(tetramethylene glycol) (PTMG)/MDI; 1,4-BD/PCL diol/MDI; BEBP or BHBP/PCL diol/MDI; DHBP/PCL diol, 4000 Da/HDI; 1,4-BD/Poly(tetramethylene oxide) glycol/(PTMO) MDI; or BD+DMPA/PCL diol, 2000, 4000, 8000 Da/MDI.

6. The UCA of claim 3, wherein the SMP is a poly(styrene-co-vinyl neodecanoate-divinylbenzene) terpolymer network.

7. The UCA of claim 1, wherein the SMM is situated on one face of the substrate.

8. The UCA of claim 1, wherein the SMM is situated on two faces of the substrate.

9. The UCA of claim 1, wherein the SMM is coated over the entirety of the substrate.

10. The UCA of claim 1, further comprising an adhesive layer situated between and contacting the substrate and the SMM.

11. The UCA of claim 1, wherein the lateral curvature is concave.

12. The UCA of claim 1, wherein the SMM is a shape memory alloy (SMA).

13. The UCA of claim 1, wherein the SMM is a piezoelectric material.

14. An article, comprising a UCA according to claim 1.
